(19) United States
(12) Patent Application Publication
(10) Pub. No.: US 2011/0235337 A1
(43) Pub. Date: Sep. 29, 2011

(54) Fade Out Optical Light Masking Projector System

(75) Inventors: Mark Jacksen, Monrovia, CA (US); David Glover, Agua Dulce, CA (US); Robert Abbott, Los Angeles, CA (US)

(73) Assignee: JACKSEN INTERNATIONAL, LTD, Los Alamos, CA (US)

(21) Appl. No.: 13/070,711

(22) Filed: Mar. 24, 2011

Related U.S. Application Data
(60) Provisional application No. 61/317,169, filed on Mar. 24, 2010.

(51) Int. Cl. F21V 13/12; F21V 13/02; B23P 11/00; H05K 13/04; H05K 13/00

(52) U.S. Cl. 362/308; 362/311.01; 29/428; 29/469; 29/592.1

(57) ABSTRACT

A light projector system, including a light projector device having a light source for producing a light beam, a light mask, an objective focal lens disposed within the path of the light beam, and a gate area. The light projector system also includes a diffusion element disposed within or forward of the gate area along the path of the light beam of the projector device. The diffusion element eliminates visible chromatic aberration from an illumination zone produced by the light projector system.

### CROSS-REFERENCES TO RELATED APPLICATIONS

This application claims the benefit of Provisional Application Ser. No. 61/317,169, filed Mar. 24, 2010, the contents of which are incorporated by reference.

### BACKGROUND

1. Field

These embodiments relate generally to optical light masking projector assemblies.

2. Description of Related Art

To avoid confusion with light beam shapers, a different product class, it is important to distinguish between the two. An optical light masking projector assembly is a different instrument than a light beam shaper assembly. Both are widely used in the Architectural and Theatrical lighting industries. Lighting specifiers select one or the other by application. Light beam shapers do not make use of a Light Mask (2) having an Opaque Light Masking Edge (7) element, and the resulting shape of the Illumination Zone (10) produced by a light beam shaper assembly is limited to shapes controlled optically such as circular, oval, or elongated. In contrast, optical light masking projector assemblies do make use of a Light Mask (2) having an Opaque Light Masking Edge (7) elements to create unlimited, customized shapes for the Illumination Zones (10) they produce. Optical light masking projector assemblies are used when the illumination zone shape is beyond a light beam shaper's optical system capabilities. The Light Mask (2) in an optical light masking projector assembly can deliver a four-sided rectilinear shape; images such as custom logos, stars, clouds, etc.; to follow the contour of irregular shaped objects such as sculpture; to project multiple beams of light such as illuminating two paintings from one projector or projecting multiple images from one projector having multiple light mask openings.

To avoid confusion with visual slide projectors used in the Audio Visual Industry, it is important to distinguish between the two. A visual slide projector projects images from a photographed transparency that are cooled by a fan motor. The projected photographic images are normally dynamic and not viewed for long periods of time. Therefore, heat degradation of the transparency is minimized. In contrast optical light masking projectors do not usually make use of fans and the projected images are normally static and viewed for long periods of time. Therefore optical light masking projectors rarely make use of a photographed transparency since the transparency will degrade and not sustain the static high heat environment of an optical light masking projector.

The purpose of an Optical Light Masking Projector Assembly (20A) is to confine light using a high temperature resistant Light Mask (2) having Opaque Light Masking Edge (7) elements, focus the masked light using an Objective Focal Lens (3), and project the resulting customized Illumination Zone (10) shape onto a surface where it can be seen as a static image.

An Optical Light Masking Projector Assembly (20A) is used when a precise high quality static illumination is desired. The subject being lit or pattern projected by the Optical Light Masking Projector Assembly (20A) seems almost magically illuminated. Details and colors “come to life” when lit by flattering light that highlights the subject only. The distinguishing characteristic of an illumination produced by the Optical Light Masking Projector Assembly (20A) is that this magical light stops precisely at the edge of the Illumination Zone (10) with no bleeding or feathering. In this high contrast, binary illumination, the subject alone is bathed in light, while the surrounding area is dark. It is at the abrupt high contrast light/dark edge, referred to here as the Binary Illumination Zone Edge (12B), where light masking problems occur. In conjunction with the Binary Illumination Zone Edge (12B), the Illumination Zone (10) exhibits a visible Chromatic Aberration Border (14). The Illumination Interior (15) may also exhibit visible Chromatic Aberration Particle (14D).

FIG. 1 is an elevation drawing that illustrates the industry standard Illumination Zone (10) produced by Optical Light Masking Projector Assemblies (20A). The Illumination Zone (10) includes at least three characteristics: a fairly uniform Illumination Interior (15), an undesired visible Chromatic Aberration Border (14) and a Binary Illumination Zone Edge (12B); all bordered by the high contrast Surrounding Dark Area (16). FIG. 1 also illustrates a fourth characteristic, visible Chromatic Aberration Particle (14D) that can at least occur when dirt or dust exists on a either a Condensing Lens (5) or a Glass Light Mask Plate (2B) when the Optical Light Masking Projector Assembly (20A) includes a Condensing Lens (5) component or a Glass Light Mask Plate (2B) component. Furthermore, FIG. 1 also illustrates a fifth characteristic, a visible Light Masking Edge Flaw (13B) that most often occurs on an Optical Light Masking Projector Assembly (20A) that utilize a field cut, Metal Light Mask Plate (2C) component or Glass Light Mask Plate (2B) component.

The basic components for an Optical Light Masking Projector Assembly (20A) are described below.

FIG. 2 is an isometric drawing showing the three essential components that an Optical Light-Masking Projector Assembly (20A) employs to achieve its results:
1. Light Source (1)
2. Light Mask (2) including a Plate (22) element having an Opaque Light Masking Edge (7) element
3. Objective Focal Singlet Lens (3A)

FIG. 2 shows: the Light Source (1) provides light; the Light Mask (2) with an Opaque Light Masking Edge (7) element gives shape to the light beam; and one or more Objective Focal Singlet Lenses (3A) serves to focus the light beam shape as well as control the diameter of the Outbound Light Beam (6) to produce the Illumination Zone (10).

The Light Source (1) component in an Optical Light Masking Projector Assembly (20A) is typically a halogen or metal halide lamp, but could be any other visible light source type. Sometimes, an Integrated Reflector Light Source (1A) is used. In some expressions of the Light Source (1), the Reflector (0) is separate; and not all Optical Light Masking Projector Assemblies (20A) use a Reflector (0). An optical light masking projector assembly rarely includes a fiber optic light source and although not yet on the market, the light source could be a new technology such as an induction lamp, a plano lamp or a light emitting diode(s); with all possibly including their own integral optical element(s).

In our drawings and discussion, specific light masks are designated with the reference number 2 and a letter. Light Mask (2) indicates an unspecified type of light mask, and is used whenever specificity is not required.

A Light Mask (2) component in an Optical Light Masking Projector Assembly (20A) includes a Plate (22) element having an Opaque Light Masking Edge (7) element to “confine” light to a specific size and “shape” emitted from the Optical Light Masking Projector Assembly (20A). The opening in a Light Mask (2) provides a light path for unblocked light to pass through that is shaped by an Opaque Light Masking Edge (7) or series of Opaque Light Masking Edges (7).

Light Mask (2) can take many forms; the forms range from photographic imaging on metal or glass substrates performed in the field, to various field adjustable shutters or mechanically adjusted iris-type devices, to pre-manufactured plates or the types that are created by technicians in the field as they cut or scrape away masking material to allow light to pass through. Designers' demands and the physical requirements of the installation typically dictate the specific light-masking form used for a given Optical Light Masking Projector Assembly (20A) installation.

FIGS. 3A, 3B contain isometric drawings that show some of the variety and complexity that Light Masks (2) and Light Masking Edges (7) may take. FIG. 3A shows Light Mask Shutter (2A) that can be positioned (moved) within the Light Mask Retainer (21A) areas to field adjust Light Mask Shutters (2A) either radially along the light path axis and/or in and out perpendicular to the light path axis tailoring the size and shape of the rectilinear-shaped Illumination Zone (10) they create. FIG. 3A includes: Integrated Reflector Light Source (1A), Light Mask Retainers (21A), Light Mask Shutter (2A) components with each including an opaque Plate (22) element having an Opaque Light Masking Edge (7) element, and Objective Focal Singlet Lenses (3A).

FIG. 3B shows several examples of what additional forms of Light Masks (2B-E) might look like. Positioned forward the Light Mask Retainer (21A) slot is a Glass Light Mask Plate (2B) component including a transparent Plate (22) element with an applied layer of a Light Blocking Material (2Z) element having two Opaque Light Masking Edge (7) opening elements showing cloud patterns, which are seen in the illustrated dual Illumination Zone (10), with a visible Chromatic Aberration Border (14) and Binary Illumination Zone Edge (12B). The Metal Light Mask Plate (2C) component includes an opaque Plate (22) element with a field cut Opaque Light Masking Edge (7) opening element showing another method of creating a rectilinear-shaped Illumination Zone (10) with its Illumination Interior (15), Visible Chromatic Aberration Border (14), and Binary Illumination Zone Edge (12B) not shown in this illustration. The Light Mask Gobo/Pattern (2D) component includes an opaque Plate (22) element having an Opaque Light Masking Edge (7) opening element showing a pre-fabricated light mask plate supplied to create a company logo or other patterned effect as the shape for the Illumination Zone (10) with its Illumination Interior (15), visible Chromatic Aberration Border (14), and Binary Illumination Zone Edge (12B). The Iris Light Mask (2E) component partially includes a series of movable opaque Plate (22) elements that cause a field adjusted circular Opaque Light Masking Edge (7) opening element resulting in a size-adjustable circular Illumination Zone (10) with its Illumination Interior (15) feature, visible Chromatic Aberration Border (14), and Binary Illumination Zone Edge (12B).

When the Optical Light Masking Projector Assembly (20A) includes a Glass Light Mask Plate (2B) component, the Illumination Zone (10) can include a negative image Interior Dark Area (16A) as shown in FIG. 4.

FIG. 4 is an isometric drawing demonstrating one of many possible Illumination Zones. Zone (10) images from a Glass Light Mask Plate (2B). An area of the glass Plate (22) element is absent of the Light Blocking Material (2Z) element providing a path for unblocked shaped light to form the Illumination Zone (10). The Illumination Zone (10) includes an Interior Dark Area (16A) having a Chromatic Aberration Border (14) perimeter that has a Binary Illumination Zone Edge (12B) that is surrounded by an Illumination Interior (15) that is surrounded by a second Chromatic Aberration Border (14) that also has a Binary Illumination Zone Edge (12B) followed by a surrounding Dark Area (16).

Cost effective spherical Objective Focal Singlet Lens (3A) components in Optical Light Masking Projector Assemblies (20A) are the universal choice for use in focusing the Outbound Light Beam (6). An Objective Focal Singlet Lens (3A) can be provided as a limited one-size-for-all, or be custom chosen to match the focal length requirements of individual installations. The goal is to produce an Outbound Light Beam (6) that is the correct diameter for the application by choosing the lens with the correct focal length. There can be more than one Objective Focal Singlet Lens (3A) components in an optical light masking projector assembly.

Objective Focal Singlet Lenses (3A) are at least one of the causes of existing Optical Light Masking Projector Assembly (20A) problems including: the visible Chromatic Aberration Border (14), Curved Edge Distortion (13), and the Binary Illumination Zone Edge (12B).

Most manufacturers of Optical Light Masking Projector Assemblies (20A) have settled on four basic configurations, illustrated by drawings FIGS. 5-8. Other variations and combinations to these configurations are also in use today.

FIG. 5 is an isometric drawing showing a more complex configuration of an Optical Light Masking Projector Assembly (20A), and its configuration includes a higher number of optical lens components, which can be fewer or greater than the illustration shows. The Condensing Lenses (5) used in this profile serve to align the light prior to reaching the Light Mask (2). FIG. 5 illustrates the Optical Light Masking Projector Assembly (20A) configuration to include the following components: Reflector (0), Light Source (1), Condensing Lenses (5), Light Mask (2) including a Plate (22) element having an Opaque Light Masking Edge (7) opening element, Objective Focal Singlet Lens (3A); and shows the resulting Outbound Light Beam (6), and Illumination Zone (10) with its Illumination Interior (15), visible Chromatic Aberration Border (14), visible Chromatic Aberration Particle (14D) and Binary Illumination Zone Edge (12B).

FIG. 6 is an isometric drawing showing the use of only one optical-quality lens, and has an Integrated Reflector Light Source (1A). FIG. 6 illustrates an Optical Light Masking Projector Assembly (20A) configuration to include the following components: Integrated Reflector Light Source (1A), Light Mask (2) including a Plate (22) element having an Opaque Light Masking Edge (7) opening element, Objective Focal Singlet Lens (3A); and shows the resulting Outbound Light Beam (6), and Illumination Zone (10) with its Illumination Interior (15), visible Chromatic Aberration Border (14), and Binary Illumination Zone Edge (12B).

FIG. 7 is an isometric drawing showing the use of only one optical-quality lens, but here the Reflector (0) is separate from the Light Source (1) component. FIG. 7 illustrates an Optical Light Masking Projector Assembly (20A) configuration to include the following components: Reflector (0), Light Source (1), Light Mask (2) including a Plate (22) element having an Opaque Light Masking Edge (7) opening element, Objective Focal Singlet Lens (3A); and shows the resulting Outbound Light Beam (6), and Illumination Zone (10) with its Illumination Interior (15), visible Chromatic Aberration Border (14), and Binary Illumination Zone Edge (12B).

FIG. 8 is an isometric drawing showing the use of a Secondary Reflector (8). The Secondary Reflector (8) serves to re-direct the Outbound Light Beam (6) axis in a direction nonparallel to the Optical Light Masking Projector Assembly (20A). The application would normally be for a recessed installation where for example an object to be illuminated is installed on a wall with the top of the object very close to a ceiling and a Secondary Reflector (8) is required to raise the Illumination Zone (10) up so that the entire object is covered by the Illumination Zone (10) including the top of the object. FIG. 8 illustrates the Optical Light Masking Projector Assembly (20A) configuration to include the following components: Integrated Reflector Light Source (1A), Light Mask (2) including a Plate (22) element having an Opaque Light Masking Edge (7) opening element, Secondary Reflector (8), Objective Focal Singlet Lens (3A), and shows the resulting Outbound Light Beam (6), and Illumination Zone (10) with its Illumination Interior (15), visible Chromatic Aberration Border (14), and Binary Illumination Zone Edge (12B).

The Gate Area (21) in an Optical Light Masking Projector Assembly (20A) is the area where a Light Mask Retainer (21A) is placed to retain a Light Mask (2) perpendicular to the light path axis. On Optical Light Masking Projector Assemblies (20A) either with or without a Condensing Lens (5), the Gate Area (21) has lateral position flexibility along the light path axis. Some Optical Light Masking Projector Assemblies (20A) even have multiple Light Mask Retainers (21A & 21B). If the lateral distance between two Light Mask Retainer positions (21A & 21B) is slight, two Light Masks (2) can be simultaneously slightly out-of-focus by the Objective Focal Lens Sub-Assembly (30) with visually acceptable close to sharp focus results from both Light Masks (2). If the lateral distance between two Light Mask Retainer positions (21A & 21B) is too great, the two Light Masks (2) cannot be simultaneously in-focus and the in-focus position for the Objective Focal Lens Sub-Assembly (30) on one Light Mask (2) will be a little different than the in-focus position for the other Light Mask (2).

FIGS. 9A and 9B contain section drawings that show the Gate Area (21) lateral position flexibility in Optical Light Masking Projector Assemblies (20A). FIG. 9A shows an Optical Light Masking Projector Assembly (20A) configuration that does not include a Condensing Lens (5) and has a short focal length Objective Focal Lens Sub-Assembly (30). The Gate Area (21) ends at the first potential position for non-specific Objective Focal Lens (3) closest to a Light Mask (2) and starts at the furthest potential Light Mask (2) position. The first potential position for a non-specific Objective Focal Lens (3) is here defined as the lens surface closest to a Light Mask (2) with an Objective Focal Lens Sub-Assembly (30) having a short focal length and where the opening from an Opaque Light Masking Edge (7) element can be focused by a non-specific Objective Focal Lens (3) that delivers an Illumination Zone (10) having a Binary Illumination Zone Edge (12B) along with a fairly uniform Illumination Interior (15) onto a surface with a shape having good edge control determined by an Opaque Light Masking Edge (7) opening. The furthest potential Light Mask (2) position is here defined as where the opening from an Opaque Light Masking Edge (7) element can provide a path of unblocked shaped light where the shaped light can be focused by a non-specific Objective Focal Lens (3) that delivers an Illumination Zone (10) having a Binary Illumination Zone Edge (12B) along with a fairly uniform Illumination Interior (15) onto a surface with a shape having good edge control determined by an Opaque Light Masking Edge (7) opening element. The Gate Area (21) can include one or multiple Light Mask Retainers (21A & 21B) and the quantity of light mask retainer positions shown in this figure shall not bear lateral length or light mask retainer quantity limits. The two light mask retainer positions shown are solely examples of the lateral flexibility available for Light Mask (2) position options.

FIG. 9B shows an Optical Light Masking Projector Assembly (20A) configuration that includes Condensing Lenses (5) and includes a short focal length Objective Focal Lens Sub-Assembly (30). The Gate Area (21) is the lateral area starting at the last Condensing Lens (5) surface, which is the Condensing Lens (5) closest to a Light Mask (2) and ends at the first potential position for a short focal length non-specific Objective Focal Lens (3) that is the Objective Focal Lens (3) surface closest to a Light Mask (2). The first potential position for non-specific Objective Focal Lens (3) is here defined as the lens surface closest to a Light Mask (2) with an Objective Focal Lens Sub-Assembly (30) having a short focal length and where the opening from an Opaque Light Masking Edge (7) element can be focused by a non-specific Objective Focal Lens (3) that delivers an Illumination Zone (10) having a Binary Illumination Zone Edge (12B) along with a fairly uniform Illumination Interior (15) onto a surface with a shape having good edge control determined by an Opaque Light Masking Edge (7) opening element. The Gate Area (21) can include one or multiple light mask retainers and the quantity of light mask retainer positions shown in this figure shall not bear lateral limits. The two Light Mask Retainers (21A & 21B) positions shown are solely examples of the lateral flexibility available for Light Mask (2) position options.

The Objective Focal Lens Area (29) in an Optical Light Masking Projector Assembly (20A) is here defined as the area where a non-specific Objective Focal Lens(es) (3) can be placed perpendicular to the light path axis to focus a masked light Illumination Zone (10) shape onto a surface. The Objective Focal Lens Area (29) begins at the termination of the Gate Area (21) and ends at the outer surface of a non-specific Objective Focal Lens (3) furthest from the Gate Area (21). The Focal Lens Area (29) has variable lateral length flexibility dictated by where one or more Objective Focal Lens(es) (3) can be positioned to focus the masked light. The Objective Focal Lens Area (29) lateral length is dictated by an Objective Focal Lens(es) (3) focal length. Since the Objective Focal Lens(es) (3) focal length is a variable, the Objective Focal Lens Area (29) also varies in lateral length.

FIGS. 10A and 10B contain section drawings that demonstrate only as an example that the Objective Focal Lens Area (29) has substantial length flexibility in Optical Light Masking Projector Assemblies (20A). The figures shown shall not bear limits on Objective Focal Lens Area (29) lateral length, and the lateral length required is determined by a non-specific Objective Focal Lens(es) (3) focal length.

FIG. 10A shows an Optical Light Masking Projector Assembly (20A) having a wide beam Objective Focal Lens Sub-Assembly (30) with a short focal length. The Objective Focal Lens Area (29) length is short.

FIG. 10B shows the same Optical Light Masking Projector Assembly (20A) shown in FIG. 10A modified to having a narrow beam Objective Focal Lens Sub-Assembly (30) with a long focal length. The Objective Focal Lens Area (29) length is now longer compared to FIG. 10A. The Objective Focal Lens Area (29) starts at the first potential position for a short focal length Objective Focal Lens(es) (3) even though a short focal length Objective Focal Lens (3) is not shown in this figure.

Light Masks (2) include an Opaque Light Masking Edge (7) opening element or a series of Opaque Light Masking Edge (7) opening elements to confine light to a specific size, and shapes the light beam emitted from Optical Light Masking Projector Assemblies (20A). The variable opening size in a Light Mask (2) provides a light path for unblocked light to pass through with option for a variable Illumination Zone (10) size.

FIGS. 11A, 11B and 11C are isometric drawings of an Optical Light Masking Projector Assembly (20A) that demonstrate how the size of a Light Mask (2) opening affect the size of the Illumination Zone (10) with all three figures representing use of the same optical projector including use of the same focal length Objective Focal Singlet Lens (3A) and with all three figures representing to have the same distance between the Optical Light Masking Projector Assembly (20A) and the surface where the Illumination Zone (10) can be seen.

FIG. 11A shows an Optical Light Masking Projector Assembly (20A) without the Light Mask (2) installed. The Illumination Zone (10) size is at its Maximum Illumination Zone Area (10A) since the Light Mask (2) is not inserted into the Light Mask Retainer (21A).

FIG. 11B demonstrates a Light Mask (2) component including an opaque Plate (22) element having a normal size square Opaque Light Masking Edge (7) opening element inserted into the Light Mask Retainer (21A) that shapes the Illumination Zone (10) to a large square image utilizing most of the Maximum Illumination Zone Area (10A).

FIG. 11C shows a Light Mask (2) component including an opaque Plate (22) element having a small size square Opaque Light Masking Edge (7) opening element inserted into the Light Mask Retainer (21A) that shapes the Illumination Zone (10) to a small square image utilizing a small portion of the Maximum Illumination Zone Area (10A).

Optical Light Masking Projector Assemblies (20A) can be installed onto the outside of a surface, or recessed behind a surface. An Optical Light Masking Projector Assembly (20A) whether installed outside of a surface or recessed behind a surface does not remove the visible Chromatic Aberration Border (14), lessen the Edge Distortion (13), or alter the Binary Illumination Zone Edge (12B).

Regardless of configuration, an Optical Light Masking Projector Assembly (20A) delivers masked and focused light as the means to create an Illumination Zone (10) with Illumination Interior (15), visible Chromatic Aberration Border (14), and Binary Illumination Zone Edge (12B).

Optical Light Masking Projector Assemblies (20A) that utilize either a Condensing Lens (5) or a Glass Light Mask Plate (2B) are at least subject to visible Chromatic Aberration Particle (14D) in the Illumination Zone (10).

No Light Source (1) alone, with or without a reflector or with an integral optical lens such as light emitting diodes, can remove the visible Chromatic Aberration Border (14), lessen the Edge Distortion (13), or alter the Binary Illumination Zone Edge (12B) found in illuminations produced by Optical Light Masking Projector Assemblies (20A).

No Light Mask (2) with an Opaque Light Masking Edge (7) opening element can remove the visible Chromatic Aberration Border (14), lessen the Edge Distortion (13), or alter the Binary Illumination Zone Edge (12B) found in illuminations produced by Optical Light Masking Projector Assemblies (20A).

No Objective Focal Singlet Lens (3A) can remove the visible Chromatic Aberration Border (14), lessen the Edge Distortion (13), or alter the Binary Illumination Zone Edge (12B) found in illuminations produced by Optical Light Masking Projector Assemblies (20A).

Five problematic characteristics of Optical Light Masking Projector Assemblies (20A) plague the art:

1. Visible Chromatic Aberration Border (14)

2. Edge Distortion (13)

3. Light Masking Edge Flaws (13B)

4. Binary Illumination Zone Edge (12B)

5. Visible Chromatic Aberration Particle (14D)

The visible Chromatic Aberration Border (14) is a band of unwanted, distracting colored light bordering the Illumination Zone (10) that occurs at the perimeter of the Illumination Zone (10) produced by Optical Light Masking Projector Assemblies (20A) since they use Objective Focal Singlet Lenses (3A).

The visible Chromatic Aberration Border (14) inherent to Optical Light Masking Projector Assemblies (20A) cannot be effectively removed by any known cost effective method. However, using cost prohibitive Achromatic (3A & 3B) Objective Focal Lenses, also known as “Doublet” (3A) or “Triplet” (3B) lenses, can minimize (when using doublets) or possibly eliminate (when using triplets) the Visible Chromatic Aberration Border (14).

An Achromatic Doublet Objective Focal Lens (3B) can remove blue or red chromatic aberration, but might not affect yellow. Achromatic Doublet Objective Focal Lenses (3B) are costly. Achromatic Triplet Objective Focal Lenses (3C) could theoretically remove all three colors of the phenomenon, however, would be even more costly than Achromatic Doublet Objective Focal Lenses (3B).

FIGS. 12A, 12B and 12C are section drawings showing possible configurations for comparing an Objective Focal Singlet Lens (3A) to an Achromatic Doublet Objective Focal Lens (3B) and an Achromatic Triplet Objective Focal Lens (3C).

FIG. 12A, an Objective Focal Singlet Lens (3A) is illustrated showing one example of a possible optical design for a single element Objective Focal Singlet Lens (3A). An Objective Focal Singlet Lens (3A) is made of a single glass composition. The dispersion from a lens composed of a single glass composition affects primarily blue and red wavelength to have uncommon focal point errors causing chromatic aberration.

FIG. 12B, an Achromatic Doublet Objective Focal Lens (3B) is illustrated showing one optical design example for an Achromatic Doublet Objective Focal Lens (3B). Shown is an Achromatic Doublet Objective Focal Lens (3B) component that includes two separate lens elements. Applicants believe one element may be the same single component used for a standard Objective Focal Singlet Lens (3A) while the other is a Corrective Lens Element (18). Each lens element includes different materials having different levels of dispersion. The errors of one lens element are designed to compensate those of the other lens element to bring two different wavelengths of light to a common focus.

FIG. 12C, an Achromatic Triplet Objective Focal Lens (3C) is illustrated showing what the applicants believe to be one optical design example for an Achromatic Triplet Objective Focal Lens (3C). Shown is an Achromatic Triplet Objective Focal Lens (3C) component that includes three separate lens elements. Applicants believe one element may be the same single component used for a standard Objective Focal Singlet Lens (3A) while the other two are Corrective Lens Elements (18). The applicants believe each lens element may include different material with each having different levels of dispersion. The applicants believe the errors of one lens element are designed to compensate those of the other lens elements to bring three different wavelengths of light to a common focus.

There are two known cost effective methods to minimize in the field the distracting impact that the visible Chromatic Aberration Border (14) has on the illumination zone edge.

The first cost effective method is to simply locate the visible Chromatic Aberration Border (14) in an area where it will not be as noticeable. For example, the frame of a painting might be a less noticeable location for the visible Chromatic Aberration Border (14) than the edge of the painting itself. Installation technicians often make this kind of judgment in the field as they attempt to optimize performance.

The second cost effective method to minimize the distracting impact of the visible Chromatic Aberration Border (14) is to field adjust the projector Objective Focal Lens Sub-Assembly (30) slightly out-of-focus. This is referred to as “soft focus” or other similar terms. When an Optical Light Masking Projector Assembly (20A) is out-of-focus to any degree, the visible Chromatic Aberration Border (14) widens and is spread out over a greater area, diluting its intensity. The more out-of-focus, the wider the visible Chromatic Aberration Border (14) band becomes. However, the resulting loss in Illumination Interior (15) quality greatly limits the degree to which this technique can be used. Once a projector is taken more than slightly out-of-focus, the quality of the Illumination Interior (15) is dramatically adversely affected. In practice, taking an Optical Light Masking Projector Assembly (20A) completely out-of-focus enough to disperse the visible Chromatic Aberration Border (14) so that it can hardly be seen is never done because to do so completely ruins the Illumination Interior (15) light uniformity as well as ruins the Illumination Zone (10) edge control.

No known method for eliminating the visible Chromatic Aberration Border (14) from illuminations produced by Optical Light Masking Projector Assemblies (20A) is currently provided by manufacturers of Optical Light Masking Projector Assemblies (20A).

FIGS. 13A, 13B and 13C are section drawings that show the contrast between an Optical Light Masking Projector Assembly (20A) in-focus (FIG. 13A), slightly out-of-focus (FIG. 13B), and completely out-of-focus (FIG. 13C). The Objective Focal Lens Sub-Assembly (30) illustrated in these figures include the following components: Objective Focal Singlet Lenses (3) that are held into position by a Clamp (32) inside of Objective Focal Cone (31), with the Objective Focal Lens Sub-Assembly (30) position adjusted in the field either in or out of the Optical Light Masking Projector Assembly (20A). A Locking Screw (33) is used to lock into position the Objective Focal Lens Sub-Assembly (30) after field focusing the Illumination Zone (10) Binary Illumination Zone Edge (12B).

FIG. 13A shows the Optical Light Masking Projector Assembly (20A) with its Objective Focal Lens Sub-Assembly (30) correctly adjusted, in-focus. The result is a visible Narrow Width Chromatic Aberration Border (14A); this band of unwanted color is intense, and there are no flaws in the Illumination Interior (15).

FIG. 13B shows the Optical Light Masking Projector Assembly (20A) with its Objective Focal Lens Sub-Assembly (30) slightly out-of-focus, resulting in a visible Medium Width Chromatic Aberration Border (14B); this band of unwanted color is slightly less intense, and there are no appreciable flaws in the Illumination Interior (15).

FIG. 13C shows the Optical Light Masking Projector Assembly (20A) with its Objective Focal Lens Sub-Assembly (30) completely out-of-focus, resulting in a visible Wide Width Chromatic Aberration Border (14); this band of unwanted color is much less intense, but there are significant, unacceptable non-uniform light flaws in the Illumination Interior (15). Furthermore, additional types of uncontrollable Edge Distortions (13) occur, rendering it nearly impossible to create an Opaque Light Masking Edge (7) opening that conforms to a Desired Illumination Edge (11).

The second problematic characteristic inherent to an Optical Light Masking Projector Assembly (20A) is a phenomenon described here as Edge Distortion (13). Edge Distortion (13) is expressed in two general ways: “curved,” and “offset.” Curved Edge Distortion (13) may be partially the result of the curvature found on spherical optical lenses. Offset Edge Distortion (13) may be partially the result of projector placement offset from the illumination target.

FIG. 14 illustrates the hypothetical situation when only curved Edge Distortion (13) impacts the rectilinear Desired Illumination Edge (11). FIG. 14A details what occurs when a straight Opaque Light Masking Edge (7) is used: the resulting Actual Illumination Edge (12) is curved. The counter-intuitive solution to curved Edge Distortion (13) is shown in FIG. 14B, where a curved Opaque Light Masking Edge (7) is used to counteract the problem.

FIG. 15 illustrates the hypothetical situation when only offset Edge Distortion (13) impacts the rectilinear Desired Illumination Edge (11). FIG. 15A details what occurs when rectilinear Light Masking Edges (7) are used, the resulting Actual Illumination Edge (12) is trapezoidal. The counter-intuitive solution to offset Edge Distortion (13) is shown in FIG. 15B, where a trapezoidal Opaque Light Masking Edge (7) is used to create the rectilinear Actual Illumination Edge (12).

In reality, however, both curved and offset Edge Distortions (13) occur simultaneously. FIG. 16 illustrates the real life situation where both curved and offset Edge Distortions (13) are occurring when the Desired Illumination Edge (11) is rectilinear. FIG. 16A details what happens when a rectilinear Opaque Light Masking Edge (7) is used, the Illumination Zone (10) result is a curved trapezoid Illumination Zone (10). FIG. 16B shows the counter-intuitive solution, a curved trapezoidal Opaque Light Masking Edge (7) creates the desired rectilinear Actual Illumination Edge (12).

The correct Opaque Light Masking Edge (7) solution for every installation is completely unique, since the amount of both curved and offset Edge Distortion (13) varies with focal length, Opaque Light Masking Edge (7) position perpendicular to the light axis, and the location of the projector in relation to its target. As one can imagine, field adjusted Opaque Light Masking Edge (7) solutions for shapes more complex than a simple rectangle are commensurately more difficult to achieve. This difficulty presents an ongoing problem for Optical Light Masking Projector Assemblies (20A).

The multiplicity of Light Mask (2) form variations known by the art has arisen in response to industry's need to manage both, curved and offset Edge Distortion (13). Yet Edge Distortion (13) continues to limit use of Optical Light Masking Projector Assemblies (20A) because of the difficulty to create successful field adjusted Light Masking Edges (7) caused by Edge Distortion (13).

The many variables that affect Edge Distortion typically make creating field adjusted Light Masking Edges (7) too difficult for untrained technicians to attempt. The high degree of skill and experience needed to manage Edge Distortion (13) is more than most field contractors possess, limiting successful installations of Optical Light Masking Projector Assemblies (20A) to lighting industry specialists.

The difficulty of creating successful Light Mask Edges (7) caused by Edge Distortion (13) is inherent to every Illumination Zone (10) produced by Optical Light Masking Projector Assemblies (20A).

There is no known corrective optical lens to minimize offset Edge Distortion (13).

Visible Light Masking Edge Flaws (13B) are the third problematic characteristic inherent to an Optical Light Masking Projector Assembly (20A), and they constitute the single most difficult obstacle for an installation technician to overcome. Visible Light Masking Edge Flaws (13B) result from great magnification of minute errors, on an Opaque Light Masking Edge (7) itself or an Opaque Light Masking Edge (7) being miss-aligned to the Desired Illumination Edge (11).

The optics in an Optical Light Masking Projector Assembly (20) combined with both distance and angle to the illumination target magnify tiny openings in Light Masks (2) exponentially many times their original size in order to create the Illumination Zone (10). Tiny nicks or bumps on an Opaque Light Masking Edge (7) that might not be visible to the naked eye end up looking like big mistakes at the Binary Illumination Zone Edge (12B). The size of the Illumination Zone (10) is impacted by the slightest fraction of change in the Opaque Light Masking Edge (7) position perpendicular to light axis. A thin field cut sliver removed from a hand cut Opaque Light Masking Edge (7) element can easily result in the Actual Illumination Edge (12) being much larger than the Desired Illumination Edge (11).

All types of Light Masks (2) are prone to exhibit visible Light Masking Edge Flaws (13B). Even when using patented field photographed techniques such as photosensitive material applied to, a Glass Light Mask Plate (2B) or Metal Light Mask Plate (2C), field technicians frequently cause visible Light Masking Edge Flaws (13B) to occur when cutting or scraping away light blocking material to create the Opaque Light Masking Edge (7).

Machine-fabricated Light Masking Edges (7) are not immune from the problem of visible Light Masking Edge Flaws (13B). For example, Light Mask Shutters (2A) need to maintain exact precision in positioning in order to cause a visually acceptable Desired Illumination Edge (11). Although this may sound easy, it is actually a very difficult task to achieve in the field. Optical Light Masking Projector Assemblies (20A) operate at very high scorching temperatures that expand and shift Light Masks (2). Furthermore, a slight touch or slight tap to a hot shutter causes movement on a Light Mask Shutter (2A) that goes exponentially a long way in altering the Binary Illumination Zone Edge (12B) position.

There is no known method of preventing visible Light Masking Edge Flaws (13B).

FIG. 1 is an elevation drawing showing one type of a visible Light Masking Edge Flaw (13B) bump at the edge of the Illumination Zone (10) caused by a bump on an Opaque Light Masking Edge (7).

The Binary Illumination Zone Edge (12B) is the fourth problematic characteristic inherent to an Optical Light Masking Projector Assembly (20A). No matter which Light Source (1), Light Mask (2), or Objective Focal Singlet Lens (3) used, there is no illumination edge option possible other than the Binary Illumination Zone Edge (12B).

In illuminations produced by Optical Light Masking Projector Assemblies (20A), a bright light stops precisely at the edge of the Illumination Zone (10) with no bleeding or feathering onto the adjacent Surrounding Dark Area (16). This bright high contrast Binary Illumination Zone Edge (12B) sharply defines the line where the bright light stops. Some consumers find this stark high contrast appealing, but others dislike the way it looks, calling it “too perfect” or “surreal”. Aside from aesthetic considerations, the Binary Illumination Zone Edge (12B) causes technical difficulty in the field, as it intensifies and exaggerates the problems associated with the visible Chromatic Aberration Border (14), Edge Distortion (13) and Visible Light Masking Edge Flaws.

The sharp light cut-off at the Binary Illumination Zone Edge (12B) having an adjacent Surrounding Dark Area (16) visually amplifies the contrasting colors of the visible Chromatic Aberration Border (14). As discussed earlier, taking the projector slightly out-of-focus in the field is a known method of spreading the visible Chromatic Aberration Border (14) over a wider area, however, this does not change the sharp light cut-off at the Binary Illumination Zone Edge (12B).

Manufacturers of Optical Light Masking Projector Assemblies (20A) have developed a great variety of Light Mask (2) forms as a means to manage Edge Distortion (13), but the Binary Illumination Zone Edge (12B) visually compounds contrast and the difficulty of this task.

Manufacturers of Optical Light Masking Projector Assemblies (20A) have never developed a method to address visible Light Masking Edge Flaws (13B). The Binary Illumination Zone Edge (12B) having an adjacent Surrounding Dark Area (16) greatly magnifies the slightest flaws on an Opaque Light Masking Edge (7), rendering many-attempted field cut Light Masks (2) useless. Technicians must cut or scrape away material from a Light Mask (2) to a high degree of accuracy in order to create an Opaque Light Masking Edge (7) that will produce an acceptable looking Binary Illumination Zone Edges (12B). Much field time and excess material can therefore be used up in the effort to create a successful Opaque Light Masking Edge (7).

The Binary Illumination Zone Edge (12B) is an aesthetic problem for some consumers who don't like the way it looks. It increases the technical difficulty in the field to final adjust an Optical Light Masking Projector Assembly (20A) by visually amplifying the colors of the visible Chromatic Aberration Border (14), making it more difficult to control Edge Distortion (13) and magnifying visible Light Masking Edge Flaws (13B).

The fifth problematic characteristic inherent to at least some Optical Light Masking Projector Assemblies (20A) is a phenomenon described here as visible Chromatic Aberration Particle (14D). Visible Chromatic Aberration Particle (14D) is a distracting unwanted particle shadow bordered by a visible Chromatic Aberration Border (14) within the Illumination Interior (15) of the Illumination Zone (10).

The visible Chromatic Aberration Particle (14D) phenomenon occurs on at least an Optical Light Masking Projector Assembly (20A) that utilize one or both of the following components, a Condensing Lens (5) or a Glass Light Mask Plate (2B). Visible Chromatic Aberration Particle (14D) is usually caused by dirt or dust particle clinging onto a Condensing Lens (5) or transparent Plate (22) surface that partially blocks light within the Gate Area (21).

FIG. 1 is an elevation drawing showing visible Chromatic Aberration Particle (14D) in the Illumination Zone (10) that is inherent to at least some Optical Light Masking Projector Assemblies (20A).

### SUMMARY

Briefly, and in general term, disclosed embodiments include a light projector system. The system includes a light projector device including a light source for producing a light beam, a light mask, an objective focal lens disposed within the path of the light beam, and a gate area. In certain embodiments, the light projector device may be any device or combination of devices that together form a device having a light source, light mask and objective focal lens. Also, the system includes a diffusion element disposed within the gate area along the path of the light beam of the projector device.

In one embodiment, the diffusion element may be integrated with a lens to form a diffusion lens. Furthermore, the light projector device includes a reflector and the diffusion element may be integrated with the reflector. In yet another embodiment, the light projector device may include a condensing lens and the diffusion element may be integrated with the condensing lens. The light projector device may also include a prism disposed in the path of the light beam, and the diffusion element may be integrated with the prism.

Embodiments are also directed to a light projector system including a light projector device having a light source for producing a light beam, a light mask having an opaque light masking edge, an objective focal lens disposed within the path of the light beam, and a gate area. The system also includes a diffusion element integrated with the light mask and disposed within the gate area along the path of the light beam of the projector device. In one embodiment, the diffusion element is integrated with the light mask and forms at least a portion of a translucent light mask plate. The translucent light mask plate includes a light blocking material.

In another embodiment, the diffusion element may be integrated with the light mask to form at least a portion of a translucent light mask shutter, wherein the translucent light mask shutter includes a light blocking material. It has also been contemplated that the diffusion element is integrated with the light mask and forms at least a portion of a photosensitized translucent light mask plate, wherein the photosensitized translucent light mask plate includes a photosensitized layer element and a light blocking material element.

Yet another embodiment is directed to a light projector system having a light projector device with a light source for producing a light beam, a light mask, an objective focal lens disposed within the path of the light beam, and a gate area. The system also includes a diffusion element disposed forward of the gate area along the path of the light beam. In one embodiment, the diffusion element is integrated with a lens to form a diffusion lens. Also, the system may also include a reflector disposed within the path of the light beam.

In other embodiments, the diffusion element may be integrated with the reflector. Also, the diffusion element may instead be integrated with the objective focal lens. The system may also include a prism disposed within the path of the light beam, and the prism may be integrated with an objective focal lens. Still further, the diffusion element may be integrated with the prism having an integral objective focal lens. In another embodiment, the system may also include a corrective lens disposed within the path of the light beam, and the diffusion element may be integrated with the corrective lens.

Further embodiments are directed to a method for creating a light projector system. The method includes providing a light source for producing a light beam, and providing a light projector device having a light mask positioned in a gate area of the light projector device and an objective focal lens positioned forward of the gate area. The light mask and objective focal lens are disposed within the path of the light beam. The method also includes positioning a diffusion element within the gate area of the light projector device and along the path of the light beam produced by the light source. The diffusion element eliminates visible chromatic aberration from an illumination zone produced by the light projector system. In one embodiment, the diffusion element may be integrated with a lens to form a diffusion lens.

In certain embodiments, the light source is a part of a rear sub-assembly and the diffusion element is a part of a front sub-assembly, and the method further includes attaching the front sub-assembly to the rear sub-assembly to create the light projector system. The method may also include securing the rear sub-assembly adjacent to the front sub-assembly.

In one embodiment, the light source is housed within the light projector device. However, it has also been contemplated that the light source is not located within the light projector device.

Another embodiment is directed to a method for creating a light projector system, and the method includes providing a light source for producing a light beam. The method also includes providing a light projector device having a light mask positioned in a gate area of the light projector device, and an objective focal lens positioned forward of the gate area. Also, a diffusion element is positioned forward of a gate area of the light projector device and along the path of the light beam produced by the light source. The diffusion element eliminates visible chromatic aberration from an illumination zone produced by the light projector system. Also, the diffusion element may be integrated with a lens to form a diffusion lens.

In one embodiment of this method, the light source is a part of a rear sub-assembly and the diffusion element is a part of a front sub-assembly. The method may include attaching the front sub-assembly to the rear sub-assembly to create the light projector system. Also, the method may include securing the rear sub-assembly adjacent to the front sub-assembly.

In one embodiment of this method, the light source is housed within the light projector device. However, it has also been contemplated that the light source is not located within the light projector device.

Other features and advantages will become apparent from the following detailed description, taken in conjunction with the accompanying drawings, which illustrate by way of example, the features of the various embodiments.

### BRIEF DESCRIPTION OF THE DRAWING

FIG. 1 depicts a schematic elevation showing characteristics for an illumination zone from an optical light masking projector;

FIG. 2 depicts an isometric drawing showing three essential components required for an optical light masking projector and resulting illumination zone;

FIGS. 3A and 3B depict isometric drawings showing optical light masking projector components, various light mask options and resulting illumination zones;

FIG. 4 depicts an isometric drawing showing optical light masking projector components combined with a light mask having an interior dark area and resulting illumination zone;

FIG. 5 depicts an isometric drawing showing optical light masking projector components combined with condensing lenses and resulting illumination zone;

FIG. 6 depicts an isometric drawing showing optical light masking projector components combined with an integrated reflector light source and resulting illumination zone;

FIG. 7 depicts an isometric drawing showing optical light masking projector components combined with a reflector separate from a light source and resulting illumination zone;

FIG. 8 depicts an isometric drawing showing optical light masking projector components combined with a secondary reflector to re-direct light and resulting illumination zone;

FIGS. 9A and 9B depict section drawings showing optical light masking projector gate areas;

FIGS. 10A and 10B depict section drawings showing optical light masking projector objective focal lens areas;

FIGS. 11A and 11B and 11C depict isometric drawings showing how the size of the illumination zone varies between an optical light masking projector having no light mask, a normal size opening light mask and a small size opening light mask;

FIGS. 12A and 12B and 12C depict section drawings comparing possible configurations between an objective focal singlet lens and achromatic objective focal lenses;

FIGS. 13A and 13B and 13C depict section drawings comparing an optical light masking projector being in-focus, slightly out-of-focus and completely out-of-focus and the resulting illumination zones;

FIGS. 14A and 14B depict isometric drawings demonstrating curved edge distortion and the light masking edge method used to counteract the distortion;

FIGS. 15A and 15B depict isometric drawings demonstrating offset edge distortion and the light masking edge method used to counteract the distortion;

FIGS. 16A and 16B depict isometric drawings demonstrating both curved edge distortion and offset edge distortion occurring simultaneously and the light masking edge method used to counteract the distortions;

FIGS. 17A and 17B and 17C depict isometric and section drawings demonstrating three fundamental diffusion element design types;

FIG. 18A depicts a schematic elevation drawing showing an illumination zone to include a fade out border having a binary illumination zone edge;

FIG. 18B depicts a schematic elevation drawing showing an illumination zone to include a fade out border having a diffused illumination zone edge;

FIG. 19A depicts a section drawing showing the diffusion element positioned within the start of the gate area and the possible illumination zone to include a fade out border having a binary illumination zone edge;

FIG. 19B depicts a section drawing showing the diffusion element positioned within the end of the gate area and the possible illumination zone to include a fade out border having a diffused illumination zone edge;

FIG. 20 depicts an isometric drawing showing an embodiment including a diffusion element;

FIG. 21 depicts a section drawing showing an embodiment including a diffusion element;

FIG. 22 depicts a section drawing showing the diffusion element positioned forward the optical light masking projector assembly;

FIGS. 23A and 23B depict a section drawings showing the diffusion element integrated with a reflector positioned forward the optical light masking projector assembly;

FIGS. 24A and 24B depict a section drawings showing the diffusion element integrated with a reflector and being part of the optical light masking projector assembly;

FIG. 25 depicts a section drawing demonstrating the diffusion element integrated with a condensing lens;

FIG. 26 depicts a section drawing demonstrating the diffusion element integrated with an objective lens;

FIGS. 27A and 27B depict an isometric and section drawings showing the diffusion element integrated with a translucent light mask plate;

FIGS. 28A and 28B depict an isometric and section drawings showing the diffusion element integrated with a translucent light mask shutter;

FIGS. 29A and 29B depict an isometric and section drawings showing the diffusion element integrated with a translucent light mask plate that includes a photosensitized layer;

FIG. 30A depicts a section drawing showing a center diffusion element design type along with a possible illumination zone result;

FIG. 30B depicts a section drawing showing a peripheral diffusion element design type along with a possible illumination zone result;

FIG. 31 depicts a section drawing showing a center diffusion element design type positioned outside the optical light masking projector with a possible illumination zone result;

FIG. 32 depicts a section drawing showing a peripheral diffusion element design type positioned outside the optical light masking projector with a possible illumination zone result;

FIG. 33 depicts a section drawing that demonstrates combining an objective lens having integral diffusion with a corrective lens element;

FIG. 34 depicts a section drawing that demonstrates retrofitting a recessed light into a fade out optical light masking projector by positioning a front sub-assembly into the light path;

FIG. 35 depicts an isometric drawing demonstrating components for the front sub-assembly used to retrofit a recessed light;

FIG. 36 depict a section drawing demonstrating the illumination zone from a recessed light retrofitted into a fade out optical light masking projector;

FIGS. 37A and 37B depict a section drawings illustrating an optical light masking projector having a straight cone retrofitted into a fade out optical light masking projector with a periscope cone;

FIG. 38 depicts a section drawing showing a fade out optical light masking projector to include a prism;

FIG. 39 depicts a section drawing showing a fade out optical light masking projector to include a prism with integral diffusion;

FIG. 40 depicts a section drawing illustrating a fade out optical light masking projector to include a prism with integral objective focal lens;

FIG. 41 depicts a section drawing illustrating a fade out optical light masking projector to include a prism with integral objective focal lens and integral diffusion; and

FIG. 42 depicts a section and isometric drawing illustrating a light mask shutter to include an adjustment tool slot.

### DETAILED DESCRIPTION

Referring now to the drawings, which are provided by way of example and not limitation, embodiments of the Fade Out Optical Light Masking projector System (100) use a non-specific Diffusion Element (4) as a constituent part of non-specific component forms that include the non-specific Diffusion Element (4) with non-specific Diffusion Element (4) being a constituent part of the non-specific component forms, that when placed within or forward of the Gate Area (21), including outside of an optical light masking projector assembly, are capable of causing light to scatter. The action of causing light to scatter can be the result of transmission through, reflection from, or a combination of transmission and reflection, from a component form within or forward of the Gate Area (21), including outside of an optical light masking projector assembly. All forms, types and methods of modification, fabrication, and/or composition of the internal body or external surfaces of any non-specific component form for the purpose of scattering light, that is, the creation of the non-specific Diffusion Element (4) as a constituent part of any non-specific component form for use within or forward of the Gate Area (21), including outside of an optical light masking projector assembly may be included in different embodiments.

The Diffusion Element (4) appears as a constituent part of a component form, and for purposes of illustration only is depicted in certain component forms, but the Diffusion Element (4) is itself a unique non-specific element. The Diffusion Element (4) is not dependent upon component form, Diffusion Element (4) design type, method of fabrication, or composition. The Diffusion Element (4) is the constituent part of a non-specific component form positioned within or forward of the Gate Area (21) of an optical light masking projector assembly including outside of an optical light masking projector assembly, capable of causing light to scatter to create at least one novel result without specificity to Diffusion Element (4), design type, material, composition, construction, including without specificity to the Diffusion Element (4) on the surface or within the component form.

A non-specific component form is here defined as any component form including the Diffusion Element (4) as a constituent part of the component without specificity to component design, component construction or component material where the component form including Diffusion Element (4) can cause light to scatter to create at least one novel result either through transmission, reflection or a combination of both when the component form is positioned within or forward of the Gate Area (21) including outside of an optical light masking projector assembly. By way of example and not by way of limiting component forms including the non-specific Diffusion Element (4), component forms can include: a lens, a light mask plate, a light mask shutter, a condensing lens, an objective lens, a prism, a reflector.

Modification, fabrication, including composition of the internal body or external surfaces of a component form to create the Diffusion Element (4) for use within or forward of Gate Area (21), including outside of an optical light masking projector assembly, may be achieved in many ways, for example, but not limited to: abrasive blasting, etching, laser hologram, molding, slumping, forming, application, impressing, fusion, secondary fusion, secondary polishing, inclusion, suspension, material uses or combination of methods. Many possible material uses, modification, and fabrication methods may be used to create the Diffusion Element (4).

Regardless of material, modification, or fabrication method, the level of diffusion for the non-specific Diffusion Element (4) constituent part of a non-specific component form must be greater on a component form positioned within the Gate Area (21) compared to the non-specific Diffusion Element (4) positioned within or forward the Objective Focal Lens Area (29) where a lower level of diffusion is required. When a non-specific component form includes a transparent glass composition as the carrier for the constituent Diffusion Element (4), consistent Fade Out Border (17) results can occur when the level of diffusion ranges from, a surface modified by an abrasive blasting media for some Diffusion Element (4) positions within the Gate Area (21), to a surface modified by an abrasive blasting media followed by subsequent secondary acid polishing for a Diffusion Element (4) positioned within or forward the Objective Focal Lens Area (29). The material composition, fabrication, and modification methods described are by way of example and not by way of limiting how to achieve the constituent Diffusion Element (4) portion of the component form.

Diffusion Element

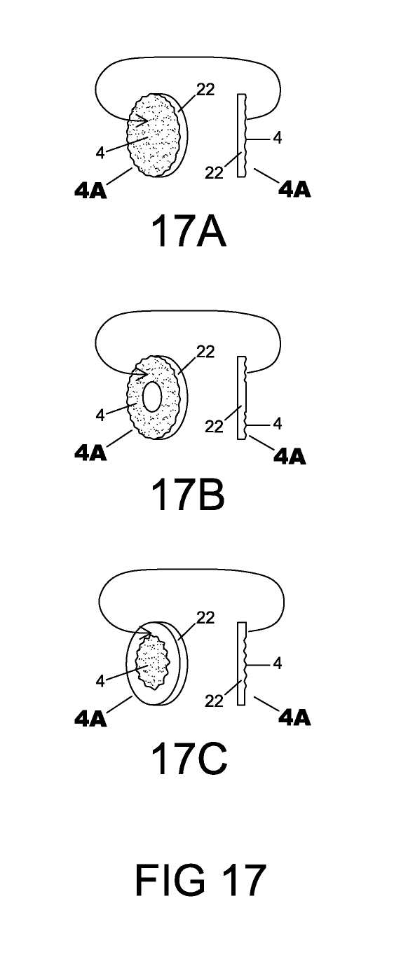

The Diffusion Element (4) has an unlimited variety of design types, all of which may be used to achieve the desired results in the Illumination Zone (10). Three fundamental Diffusion Element (4) design types are illustrated in FIGS. 17A, 17B and 17C. These fundamental Diffusion Element (4) design types may be combined or further modified, for example by shape, offsetting, or graduation, to achieve endless patterns or variations. All Diffusion Element (4) design types including those not shown may be applied to all component forms of different embodiments.

Three fundamental diffusion design types are included herein for purposes of illustration only and not limitation: total coverage Diffusion Element (4) design type, shown in FIG. 17A; peripheral Diffusion Element (4) design type, shown in FIG. 17B; and center Diffusion Element (4) design type, shown in FIG. 17C.

FIGS. 17A, 17B and 17C demonstrate three fundamental Diffusion Element (4) design types of the Diffusion Element (4) expressed as a constituent part of a Diffusion Lens (4A) component form. A Diffusion Lens (4A) component form includes a Diffusion Element (4) and a Plate (22) element.

Diffusion Lens

The Diffusion Lens (4A) placed within or forward of the Gate Area (21), including outside of an optical light masking projector assembly, is a component form, easily adaptable to most optical light masking projector assemblies. The Plate (22) element and the Diffusion Element (4) used to form the Diffusion Lens (4A) component form may be circular in shape, but are not limited to that shape. The Plate (22) element used with the Diffusion Element (4) to form the Diffusion Lens (4A) may be transparent, but is not limited to that property. The external surface of the Plate (22) may be modified as a means to incorporate Diffusion Element (4) to form Diffusion Lens (4A), but the means of incorporating Diffusion Element (4) is not limited in any way.

FIG. 17A includes an isometric and section drawing demonstrating a Diffusion Lens (4A) component form that includes a transparent Plate (22) element combined with a Diffusion Element (4) employing the total coverage Diffusion Element (4) design type as a means of scattering light from any striking point. When the Diffusion Lens (4A) is placed within or forward of the Gate Area (21), including outside of an optical light masking projector assembly, the action of scattering light results in a novel Illumination Zone (10). Depending on Objective Focal Lens Assembly (30) focus and Diffusion Lens (4A) position within or forward of the Gate Area (21), including outside of an optical light masking projector assembly, the total coverage Diffusion Element (4) design type may cause an Illumination Zone (10) to include the following results: sometimes include a novel Fade Out Border (17) free of a visible Chromatic Aberration Border (14) finishing with a low light intensity Diffused Illumination Zone Edge (12D), sometimes include a novel Fade Out Border (17) free of a visible Chromatic Aberration Border (14) finishing with a low light intensity Binary Illumination Zone Edge (12B), and sometimes include a Diffused Illumination Interior (15D) free of visible Chromatic Aberration Particle (14D).

FIG. 17B includes an isometric and section drawing demonstrating a Diffusion Lens (4A) component form that includes a transparent Plate (22) element combined with a Diffusion Element (4) employing the peripheral Diffusion Element (4) design type as a means of scattering light striking the border of the Diffusion Lens (4A). When the Diffusion Lens (4A) is placed within or forward of the Gate Area (21), including outside of an optical light masking projector assembly, the action of scattering light results in a novel Illumination Zone (10). The peripheral Diffusion Element (4) design type may enhance light intensity at the Illumination Interior (15) from the transparent lens center. Depending on Objective Focal Lens Assembly (30) focus and Diffusion Lens (4A) position within or forward of the Gate Area (21), including outside an optical light masking projector assembly, this diffusion design type may cause an Illumination Zone (10) to include the following results: sometimes include a novel Fade Out Border (17) free of a visible Chromatic Aberration Border (14) finishing with a low light intensity Diffused Illumination Zone Edge (12D), sometimes include a novel Fade Out Border (17) free of a visible Chromatic Aberration Border (14) finishing with a low light intensity Binary Illumination Zone Edge (12B), and sometimes include a Diffused Illumination Interior (15D) free of visible Chromatic Aberration Particle (14D).

FIG. 17C includes an isometric and section drawing demonstrating a Diffusion Lens (4A) component form that includes a translucent Plate (22) element combined with a Diffusion Element (4) employing the center Diffusion Element (4) design type as a means to scatter light striking the center of the Diffusion Lens (4A). When the Diffusion Lens (4A) is placed within or forward of the Gate Area (21), including outside of an optical light masking projector assembly, the action of scattering light results in a novel Illumination Zone (10). Depending on Objective Focal Lens Assembly (30) focus and Diffusion Lens (4A) position within or forward of the Gate Area (21), including outside an optical light masking projector assembly, the center Diffusion Element (4) design type may cause an Illumination Zone (10) to include the following results: sometimes include a novel Fade Out Border (17) free of a visible Chromatic Aberration Border (14) finishing with a low light intensity Diffused Illumination Zone Edge (12D), sometimes include a novel Fade Out Border (17) free of a visible Chromatic Aberration Border (14) finishing with a low light intensity Binary Illumination Zone Edge (12B), and sometimes include a Diffused Illumination Interior (15D) free of visible Chromatic Aberration Particle (14D).

In our drawings and discussion, the Diffusion Element (4) is given the number 4 while a number followed by a letter is used for identifying a specific component form that in all instances, except for one embodiment, include a non-specific Diffusion Element (4) as a constituent part of the component form.

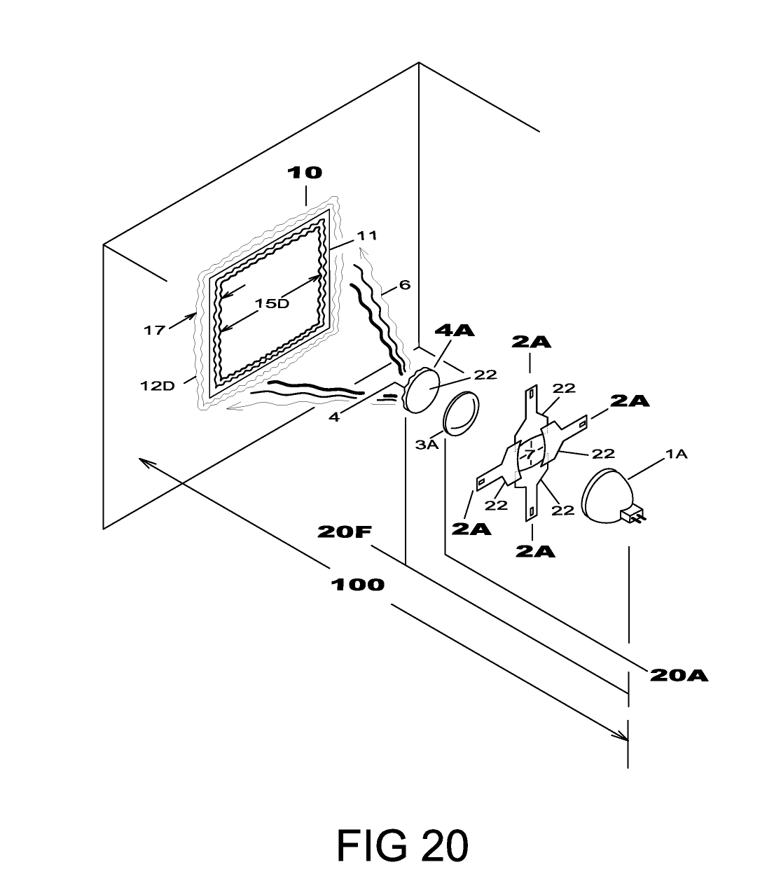

Not including the embodiments of FIGS. 20-21 and 30-32, component forms including the Diffusion Element (4) as a constituent part are therefore described without reference to, nor are limited by either, Diffusion Element (4) design type, construction, material or composition. The placement of the Diffusion Element (4) may be within or forward of Gate Area (21), including outside of an optical light masking projector assembly regardless of component form.

Our drawings employ standard drafting techniques, and also include some custom techniques to symbolize specific concepts of the embodiments. Specifically, to represent Diffusion Element (4), wavy lines are employed at the edges and/or stippled dots are shown in/on component forms. In drawings where light is shown traveling through space, wavy lines are used to represent diffused light, while straight lines are used to indicate non-diffused light. On surfaces where light hits, wavy lines represent diffused light, while straight lines indicate a binary edge.

In our drawings, the illumination at both the Illumination Zone (10) and Outbound Light Beam (6) borders will include multiple subsequent wavy lines with the inner wavy line a wider line weight representing a brighter light intensity and the in-between wavy line(s) having a narrower line weight representing a lower light intensity; this decrease in line weight represents a fade out decrease in light intensity at the Outbound Light Beam (6) and Illumination Zone (10) borders. This fade out of light intensity at the Illumination Zone (10) border is described here as the novel Fade Out Border (17).

A novel Fade Out Border (17) can finish with either a surrounding outermost, low light intensity binary edge, or a low light intensity diffused edge. In our drawings, the outermost perimeter edge of Illumination Zone (10) is depicted as either a straight line or a wavy line.

A narrow straight line at the outermost perimeter edge of Illumination Zone (10) represents the Binary Illumination Zone Edge (12B), a low light intensity binary and sharp cut-off illumination edge surrounding and finishing a Fade Out Border (17); which is one novel result.

A narrow wavy line at the outermost perimeter edge of Illumination Zone (10) represents the Diffused Illumination Zone Edge (12D), a low light intensity, soft, undefined, scattered and diffused illumination edge surrounding and finishing a Fade Out Border (17); which is one novel result.

Visual Results of Fade Out Optical Light Masking Projector

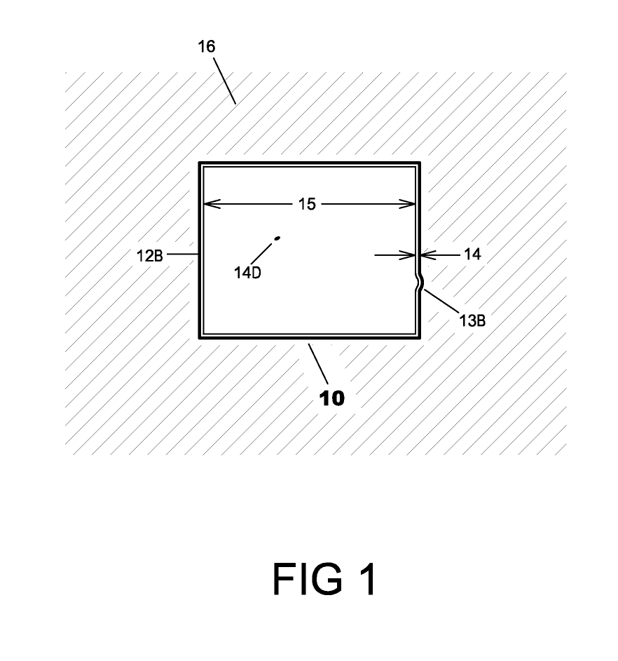

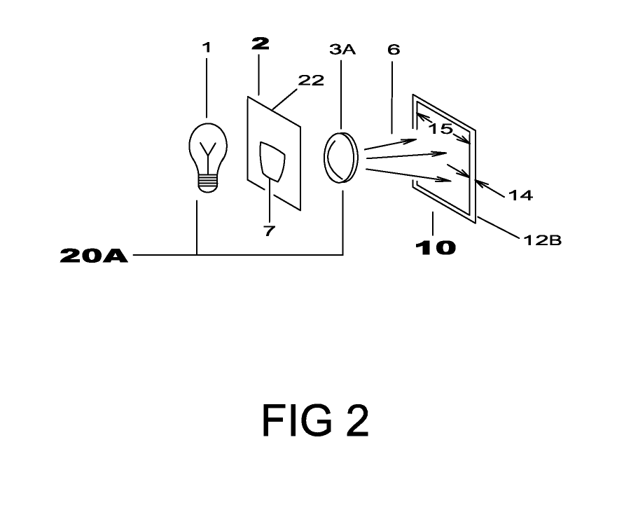

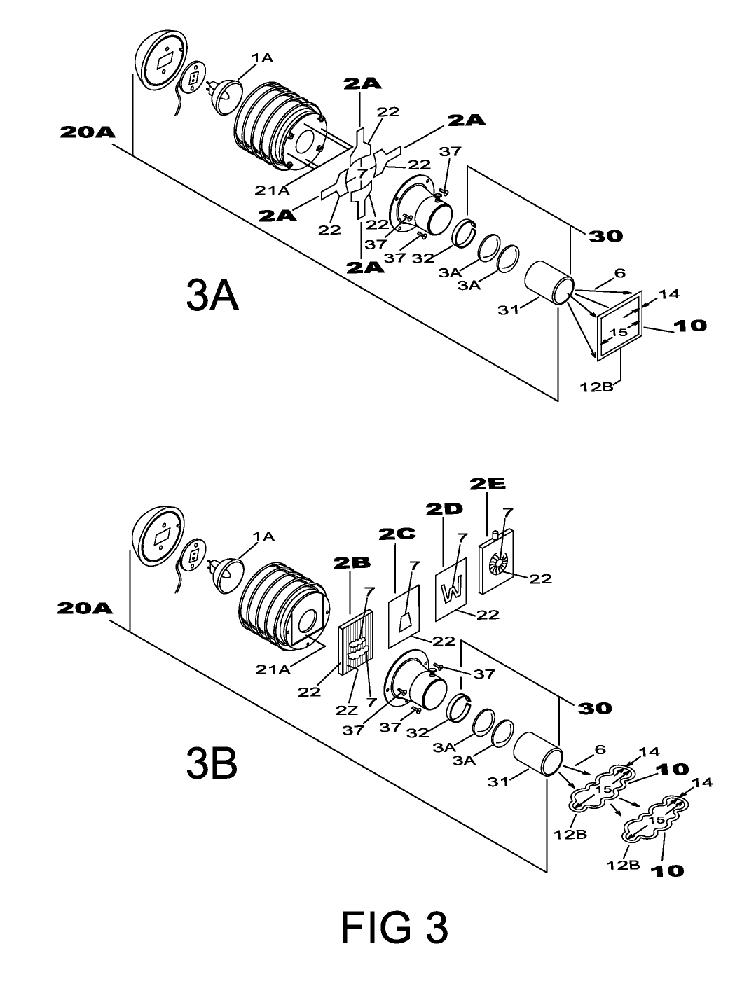

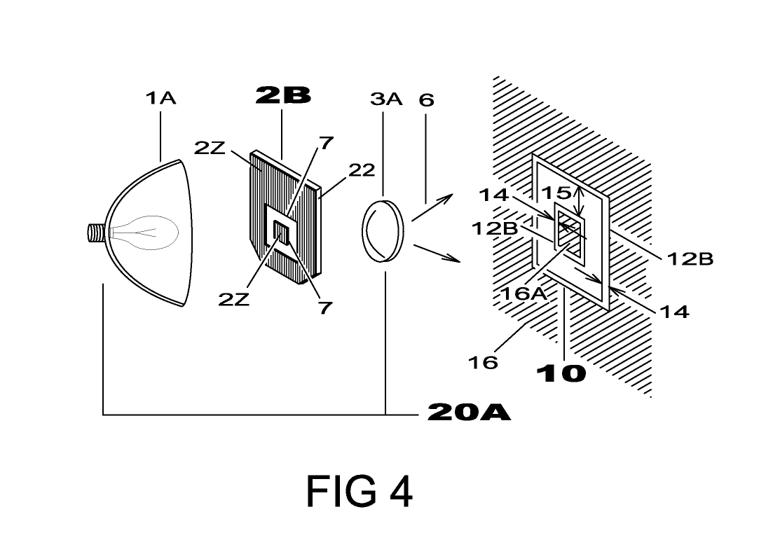

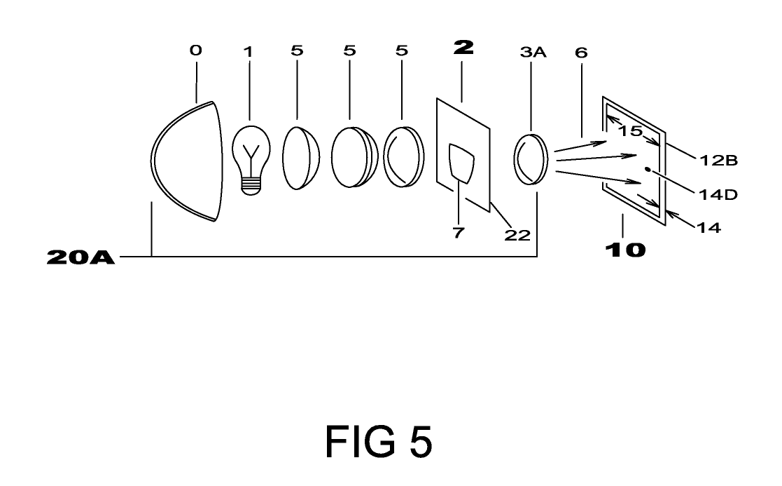

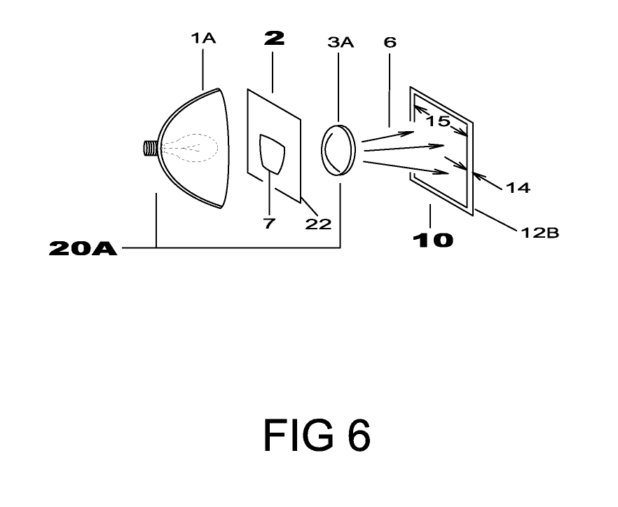

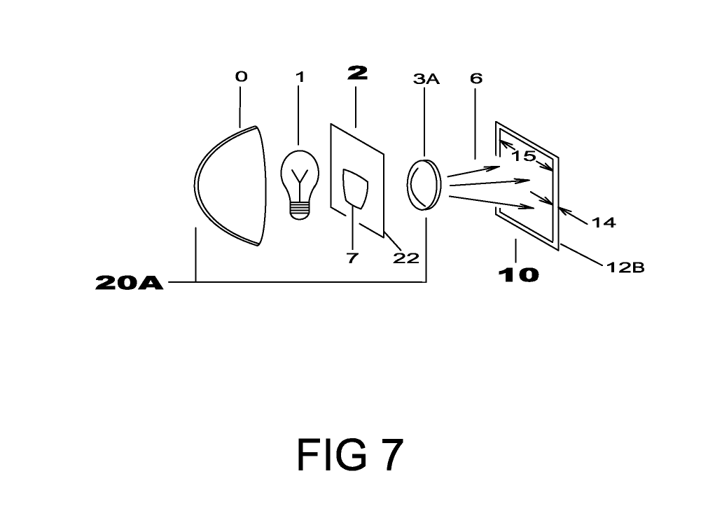

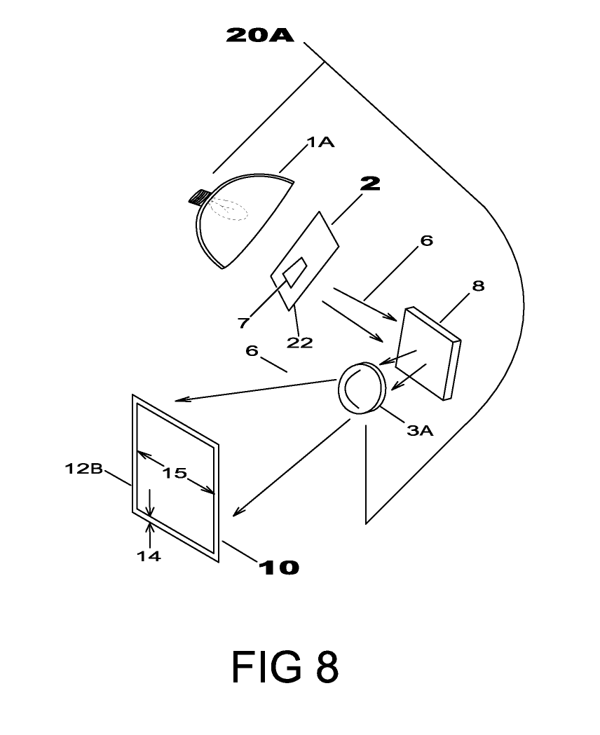

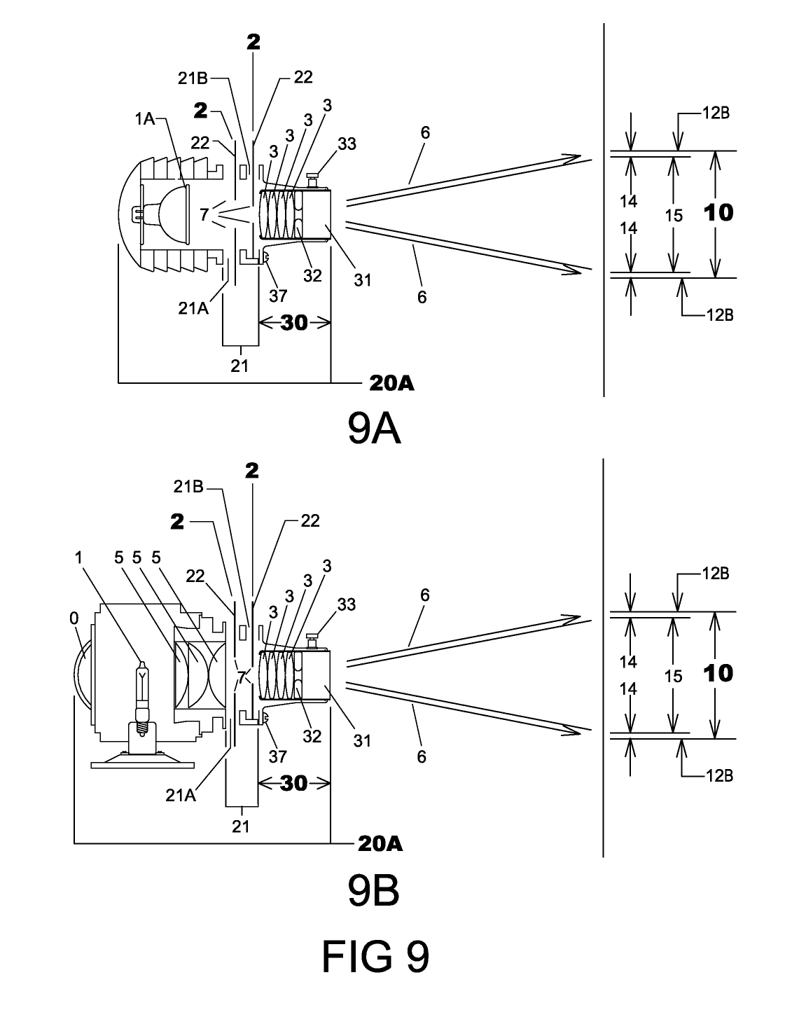

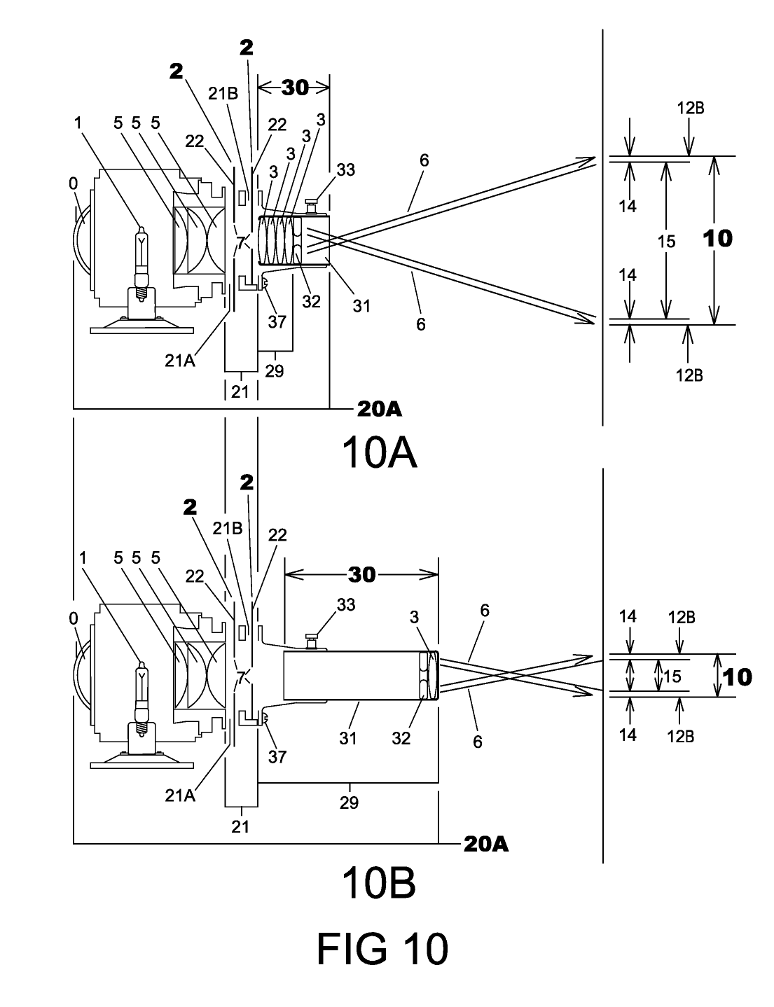

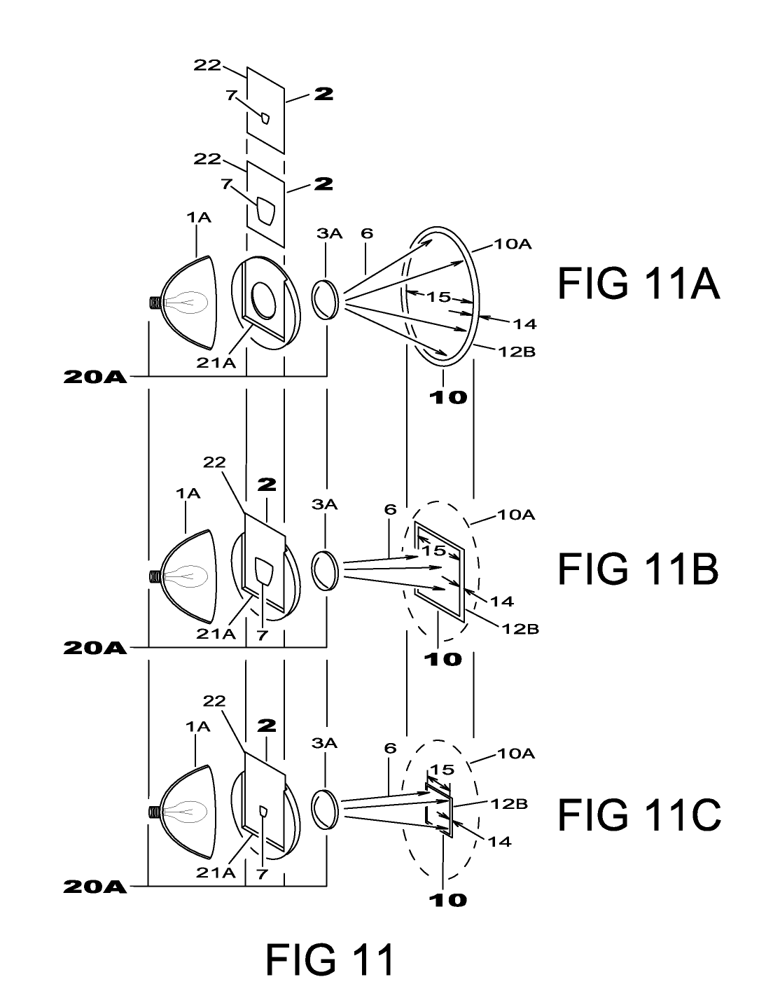

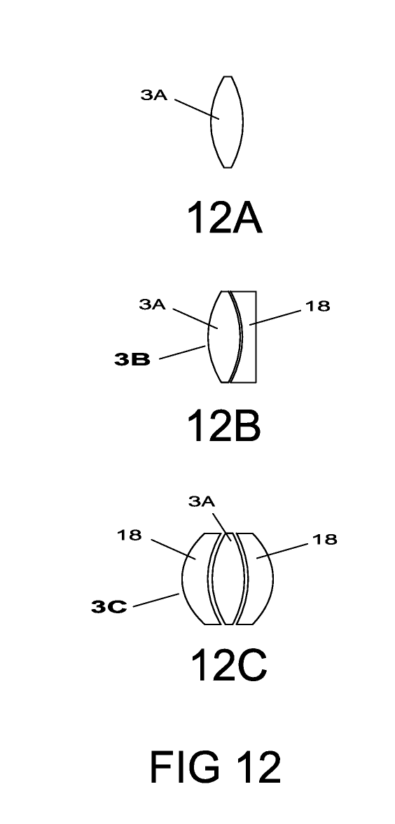

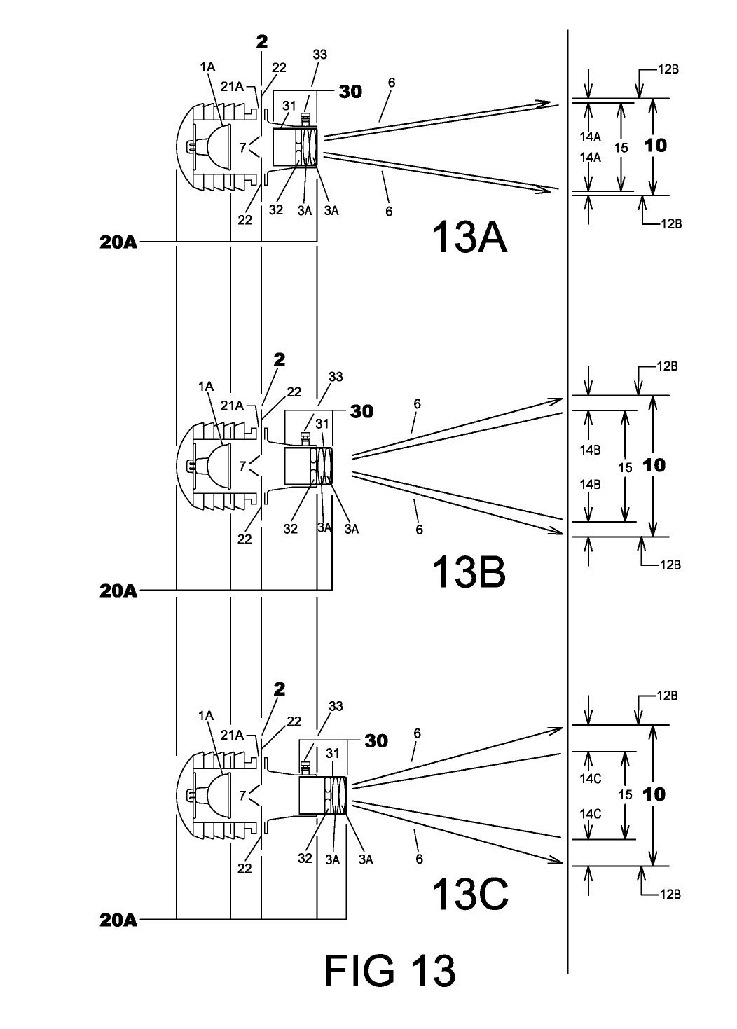

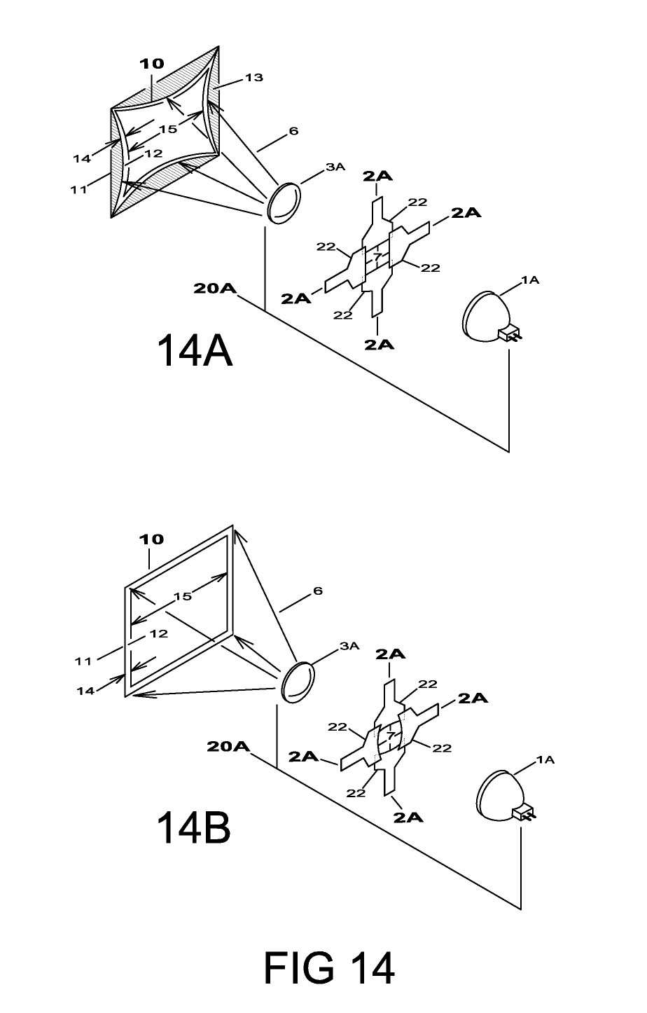

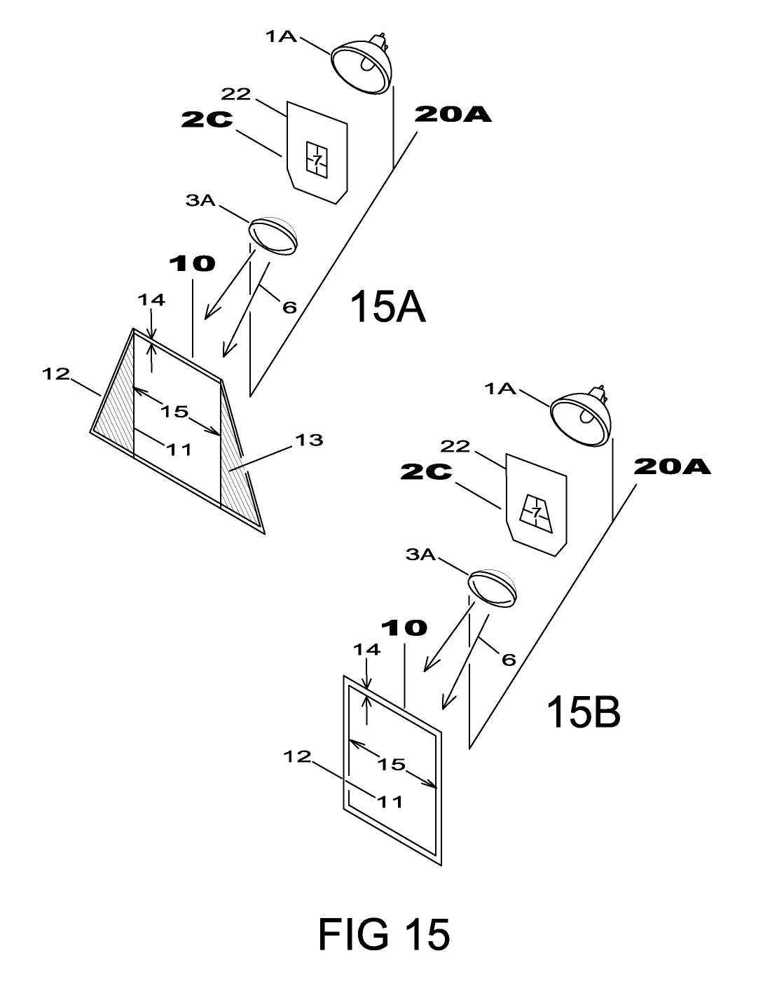

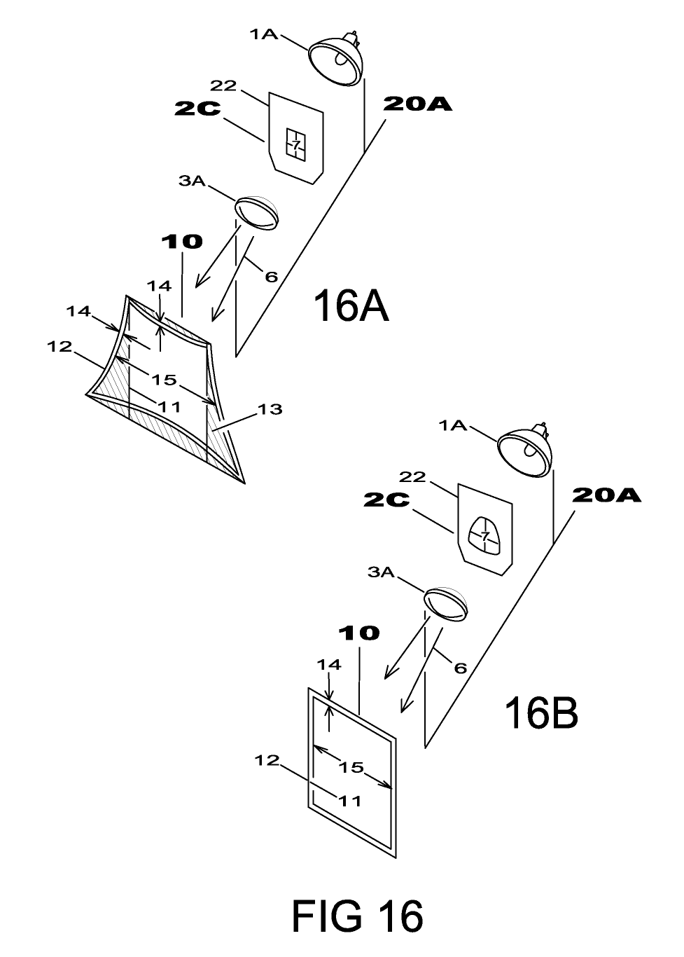

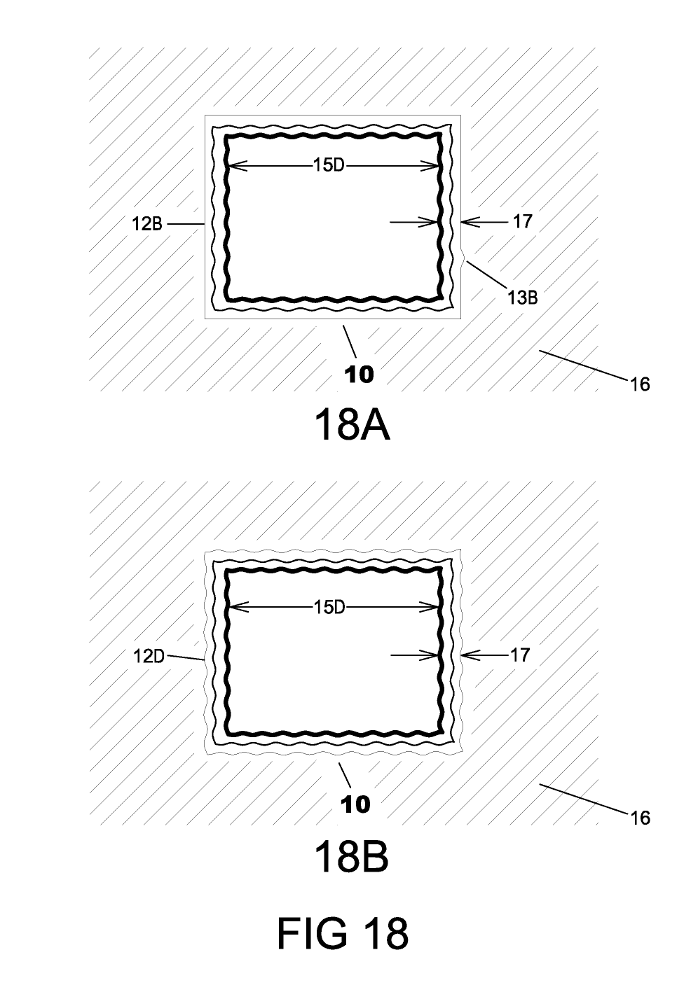

One can easily distinguish between the illumination characteristics, shown in FIG. 1, and those, shown in FIGS. 18A and 18B. Five comparisons are striking:

First, FIG. 1 shows a Chromatic Aberration Border (14), while it does not appear in FIGS. 18A, 18B because it is replaced with a Fade Out Border (17).

Second, FIG. 1 shows an Illumination Zone (10) produced by an Optical Light Masking Projector Assembly (20A) finishing with a high light intensity Binary Edge (12B) having a high intensity Light Masking Edge Flaw (13B) with high visual impact. By contrast, FIG. 18A shows a Fade Out Border (17) finishing with a low light intensity Binary Edge (12B) where a low intensity Light Masking Edge Flaw (13B) has low visual impact from a Fade Out Optical Light Masking Projector System (100).

Third, FIG. 1 demonstrates that an Optical Light Masking Projector Assembly (20A) is limited to producing a high light intensity Binary Edge (12B) at the outside edge of the Illumination Zone (10). By contrast, FIGS. 18A and 18B illustrate embodiments from Fade Out Optical Light Masking Projector Systems (100) that provide the option of producing either a low light intensity Binary Illumination Zone Edge (12B), shown in FIG. 18A, or a novel low light intensity Diffused Illumination Zone Edge (12D), shown in FIG. 18B.

Fourth, FIG. 1 shows a Chromatic Aberration Particle (14D) appearing in the interior of the Illumination Zone (10). By contrast, FIGS. 18A and 18B demonstrate that Chromatic Particles typically do not appear in Illumination Zones created by the described embodiments of the Fade Out Optical Light Masking Projector System (100).

Fifth, both FIG. 1 and FIGS. 18A and 18B reveal that existing projectors and the current embodiments produce Illumination Interiors (15, 15D) that are fairly uniform throughout, and are comparable to each other in terms of ability to illuminate targets.

The Illumination Zone (10) with a visible Chromatic Aberration Border (14) is shown in FIG. 1, and the current embodiment's novel Fade Out Border (17) free of visible chromatic aberration is shown in FIGS. 18A, 18B. Instead of an Illumination Interior (15) with fairly uniform light intensity halting abruptly at the edge of the Illumination Zone (10) as the light from an Optical Light Masking Projector Assembly (20A) illuminations does, the light from a Fade Out Optical Light Masking Projector System (100) is also fairly uniform in the illumination interior but is visually scattered at the illumination border gently tapering off in intensity as it reaches the edge of the Illumination Zone (10). This area of tapered light intensity surrounding the illumination interior is the novel Fade Out Border (17). The outermost finishing edge of and surrounding the Fade Out Border (17) may either be a novel low light intensity Diffused Illumination Zone Edge (12D) or a low light intensity Binary Illumination Zone Edge (12B).

FIGS. 18A and 18B are elevation drawings that demonstrate two fade out visual illumination results that the described embodiments produce, both results include a novel Fade Out Border (17) and both results are free of a visible Chromatic Aberration Border (14) that are transformative for optical light masking projectors. Regardless of projector configuration, including with or without a Condensing Lens (5), at least one or the other visual result can occur when a Diffusion Element (4) is positioned within or forward the Gate Area (21) including outside of an optical light masking projector with the visual result outcome dependant upon the following variables: projector configuration, Diffusion Element (4) position, level of diffusion, Objective Focal Lens(es) (3) focus, Diffusion Element (4) design type, Light Mask (2) opening size, and including a combination of two or more of the variables described. Either visual result is dependant upon the level of diffusion being greater when the non-specific Diffusion element (4) is positioned within the Gate Area (21) compared to the non-specific Diffusion Element (4) positioned within or forward the Objective Focal Lens Area (29) where a lower level of diffusion causes one or the other visual result. To achieve a visual result, combinations of the variables described will vary on projectors built differently than the projectors shown in the embodiments. Therefore the embodiments are by way of example on how to achieve the visual results using the projectors shown and not by way of limiting how to achieve the result on a projector built differently where differently can include more or less optical quality elements than shown or described in the embodiments.

FIG. 18A illustrates the first visual result that can occur with placement of a non-specific Diffusion Element (4) in positions within or forward the Gate Area (21) causing an Illumination Zone (10) to sometimes include a Diffused Illumination Interior (15D) free of visible Chromatic Aberration Particle (14D) surrounded by the Fade Out Border (17) free of a visible Chromatic Aberration Border (14) with the Fade Out Border (17) outermost perimeter edge finishing with a surrounding low light intensity Binary Illumination Zone Edge (12B).

FIG. 18B illustrates the second visual result that can occur with placement of a non-specific Diffusion Element (4) in positions within or forward the Gate Area (21) including outside of an optical light masking projector assembly causing an Illumination Zone (10) to sometimes include a Diffused Illumination Interior (15D) free of visible Chromatic Aberration Particle (14D) surrounded by the Fade Out Border (17) free of a visible Chromatic Aberration Border (14) with the Fade Out Border (17) outermost perimeter edge finishing with a surrounding low light intensity novel Diffused Illumination Zone Edge (12D).

Fade Out Optical Light Masking Projector System

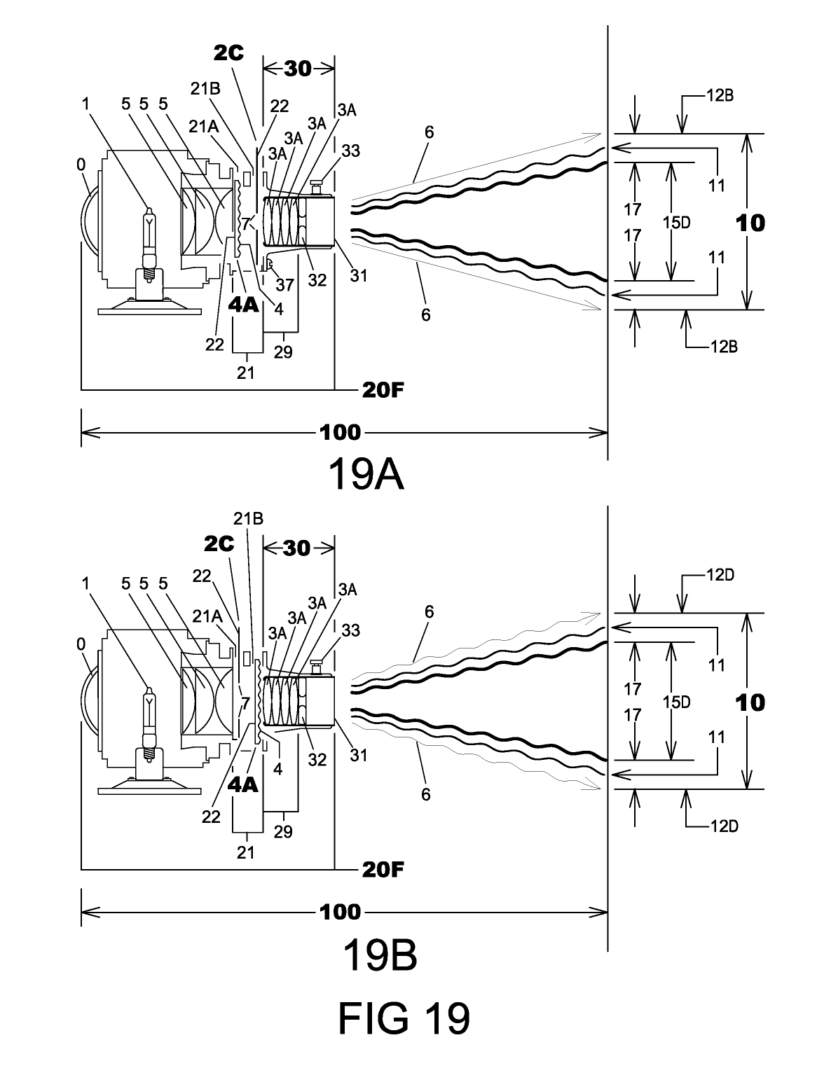

Fade Out Optical Light Masking Projector Systems (100) and methods are defined as any past, present, or future optical light masking projector assembly, including adapted Optical Light Masking Projector Assemblies (20A), that combine a non-specific Diffusion Element (4) positioned in the light path of and placed within or forward the Gate Area (21) and including the non-specific Diffusion Element (4) placed outside of the Optical Light Masking Projector Assembly (20A), with the non-specific Diffusion Element (4) capable of causing an Illumination Zone (10) on a surface where it can be seen to include a Fade Out Border (17), with the Fade Out Border (17) having two outermost finishing perimeter options, a low light intensity outermost novel Diffused Illumination Zone Edge (12D) perimeter option, or a low light intensity outermost Binary Illumination Zone Edge (12B) perimeter option, with the Illumination Zone (10) sometimes including a Diffused Illumination Interior (15D) result as part of the Illumination Zone (10). The Fade Out Optical Light Masking Projector System (100) is illustrated in FIGS. 19 through 33 and FIGS. 36 through 41.

A Fade Out Optical Light Masking Projector System (100) includes a non-specific Diffusion Element (4) in the light path of and in combination with an optical light masking projector with the non-specific Diffusion Element (4) placed within or forward the Gate Area (21) including the non-specific Diffusion Element (4) positioned outside an optical light masking projector assembly: where the non-specific Diffusion Element (4) can cause a Fade Out Border (17) to occur as part of the Illumination Zone (10); where the non-specific Diffusion Element (4) causes the Fade Out Border (17) and eliminates the visible Chromatic Aberration Border (14) from the Illumination Zone (10) perimeter; where the non-specific Diffusion Element (4) causes the Fade Out Border (17) as part of the Illumination Zone (10) with option for a low light intensity novel Diffused Illumination Zone Edge (12D) outermost perimeter finish or low light intensity Binary Illumination Zone Edge (12B) outermost perimeter finish; where the non-specific Diffusion Element (4) can cause the Fade Out Border (17) surrounded by a low light intensity outermost novel Diffused Illumination Zone Edge (12D) finish reducing the level of an Opaque Light Masking Edge (7) precision required by weakening Edge Distortion (13) and weakening Light Masking Edge Flaws (13B) thereby lessening the precision required to create by reducing the difficulty in fashioning a successful Opaque Light Masking Edge (7) that delivers a visually acceptable Desired Illumination Edge (11) occurring as part of the Illumination Zone (10); where the non-specific Diffusion Element (4) can sometimes cause a method for a Diffused Illumination Interior (15D) to occur that eliminates visible Chromatic Aberration Particle (14D) from the Diffused Illumination Interior (15D).

Fade Out Optical Light Masking Projector Assembly

A Fade Out Optical Light Masking Projector Assembly (20F) is defined as any past, present, or future optical light masking projector assembly, including adapted Optical Light Masking Projector Assemblies (20A), that include a non-specific Diffusion Element (4) positioned within or forward the Gate area (21) within the assembly.

FIGS. 19A and 19B are section drawings demonstrating Fade Out Optical Light Masking Projector Assemblies (20F) with each assembly including a Gate Area (21) and having Light Mask Retainers (21A & 21B) slots designed to accept a Diffusion Lens (4A) component form to scatter light and a Metal Light Mask Plate (2C) component form to shape light. Objective Focal Lens Assembly (30) can include one or more Objective Focal Singlet Lenses (3A) and may need to be completely out-of-focus for the non-specific Diffusion Element (4) positions shown. The Illumination Zone (10) includes, the possible Diffused Illumination Interior (15D) having a fairly uniform scattered illumination, a controlled outermost perimeter edge shape conforming to a Desired Illumination Edge (11) with the edge shape controlled by an Opaque Light Masking Edge (7).

FIG. 19A illustrates a Diffusion Lens (4A) component form that includes a Plate (22) element and a non-specific Diffusion Element (4) as a constituent part of the component to scatter light, with the component positioned directly behind a Metal Light Mask Plate (2C) close to the beginning of Gate Area (21). The Light Source (1) causes a light path through the non-specific Diffusion Element (4) and the light is scattered and then shaped by an Opaque Light Masking Edge (7) with the shaped scattered light's path through the Objective Focal Lens Assembly (30) that usually needs to be completely out-of-focus. The resulting Outbound Light Beam (6) causes an Illumination Zone (10) to usually include a brighter Diffused Illumination Interior (15D) free of visible Chromatic Aberration Particle (14D) that has a fairly uniform light intensity that is usually surrounded by a novel Fade Out Border (17) tapering light intensity free of a visible Chromatic Aberration Border (14) usually finishing with a surrounding low light intensity outermost Binary Illumination Zone Edge (12B) perimeter.

FIG. 19B illustrates a Diffusion Lens (4A) component form that includes a Plate (22) element and a non-specific Diffusion Element (4) as a constituent part of the component to scatter light, with the component positioned directly forward a Metal Light Mask Plate (2C) close to the end of Gate Area (21). The Light Source (1) causes a light path through Light Masking Edges (7) shaping light. The shaped light is scattered by the non-specific Diffusion Element (4) with the shaped scattered light's path through the Objective Focal Lens Assembly (30) that may need to be out-of-focus. The resulting Outbound Light Beam (6) causes an Illumination Zone (10) to usually include a Diffused Illumination Interior (15D) free of visible Chromatic Aberration Particle (14D) that has a fairly uniform light intensity that is usually surrounded by a novel Fade Out Border (17) tapering light intensity free of a visible Chromatic Aberration Border (14) usually finishing with a surrounding low light intensity outermost novel Diffused Illumination Zone Edge (12D) perimeter loosely conforming to a Desired Illumination Edge (11) as shown to be within the Illumination Zone (10) of FIG. 20.

The Diffusion Lens (4A) component form shown in FIGS. 19A and 19B could also be positioned anywhere within the Objective Focal Lens Area (29), and more specifically anywhere within or forward the Gate Area (21) including anywhere outside of the Optical Light Masking Projector Assembly (20A), and the non-specific Diffusion Element (4) constituent part of the component form shown as well as the component itself are not limited to the position or component design shown, and the component form as well as the non-specific Diffusion Element (4) constituent part of the component are therefore not limited to being positioned within the Gate Area(21) but instead illustrate the starting point for application of the described embodiments.

How Diffusion Element Improves Five Problems

The described embodiments teach a new method of eliminating the unwanted distracting border of colored light, the visible Chromatic Aberration Border (14) from the Illumination Zone (10) by using a non-specific Diffusion Element (4) instead of a costly Achromatic Doublet Objective Focal Lens (3B) or more costly Achromatic Triplet Objective Focal Lens (3C). The Fade Out Border (17) caused by a non-specific Diffusion Element (4) is what assists to eliminate the visible Chromatic Aberration Border (14) around an Illumination Zone (10) finishing with either a Binary Illumination Zone Edge (12B) or a Diffused Illumination Zone Edge (12D). The non-specific Diffusion Element (4) causes the Chromatic Aberration Border (14) light to scatter and blend with the illumination interior causing the Chromatic Aberration Border (14) to not be visible on a surface.

The described embodiments teach a new method to manage and method to weaken both curved and offset Edge Distortion (13) through a novel Fade Out Border (17) surrounded by a low light intensity outermost novel Diffused Illumination Zone Edge (12D) perimeter caused by a non-specific Diffusion Element (4) that reduces the difficulty of creating a successful Opaque Light Masking Edge (7) for both trained and untrained installation contractors. An Illumination Zone (10) having a novel Fade Out Border (17) finishing with a low light intensity outermost novel Diffused Illumination Zone Edge (12D) where the light is not an abrupt light/dark binary edge and does not stop precisely at the Illumination Zone (10) perimeter reduces the level of precision required at Light Masking Edges (7). The current embodiments' Illumination Zone (10) with a novel Fade Out Border (17) finishing with a low light intensity outermost novel Diffused Illumination Zone Edge (12D) weakens the level of exactness required to compensate for curved Edge Distortion (13) by reducing the counter-radius required on Light Masking Edges (7) since the visual impact of an incorrect curve on an Opaque Light Masking Edge (7) is weakened. The current embodiments' Illumination Zone (10) with a Fade Out Border (17) finishing with a low light intensity outermost Diffused Illumination Zone Edge (12D) weakens the level of exactness required to compensate for offset Edge Distortion (13) caused by projector placement offset from the Illumination Zone (10) target by reducing the visual impact of incorrect angles on Light Masking Edges (7).

There is also described a method to manage and method to weaken visible Light Masking Edge Flaws (13B) that reduces the difficulty of creating successful Light Masking Edges (7) for both trained and untrained installation contractors. An Illumination Zone (10) having a novel Fade Out Border (17) finished with a low light intensity outermost novel Diffused Illumination Zone Edge (12D) where the light is not an abrupt light/dark binary edge and does not stop precisely at the edge of the Illumination Zone (10) reduces the level of precision required at Light Masking Edges (7). The Fade Out Border (17) finished with a low light intensity Diffused Illumination Zone Edge (12D) weakens the level of exactness required at Light Masking Edges (7) weakening visual flaws at the edge of the Illumination Zone (10) otherwise magnifying minuet errors caused by misalignment or tiny nicks/bumps at Light Masking Edges (7).

Furthermore, a method is described of eliminating a Binary Illumination Zone Edge (12B) from an Illumination Zone (10) by combining a novel Fade Out Border (17) finished with a low light intensity outermost novel Diffused Illumination Zone Edge (12D) where the light is not an abrupt light/dark binary edge and does not stop precisely at the edge of the Illumination Zone (10). Although a high contrast Illumination Zone (10) without a Fade Out Border (17) finished with a Binary Illumination Zone Edge (12B) is appealing to some consumers, other consumers find it “too perfect” or “surreal”. The described embodiments provide consumers and installation contractors a retrofit option for either a Binary Illumination Zone Edge (12B) or a Diffused Illumination Zone Edge (12D) by simply inserting or not a non-specific Diffusion Element (4) into the light path of an Optical Light Masking Projector Assembly (20A) transforming the assembly into a Fade Out Optical Light Masking Projector Assembly (20F) causing new visual results from the Fade Out Optical Light Masking Projector System (100).

Aside from aesthetic considerations, the Binary Illumination Zone Edge (12B) found on Optical Light Masking Projector Assemblies (20A) also causes technical difficulty for both trained and untrained installation contractors as it intensifies and exaggerates the problems associated with: a visible Chromatic Aberration Border (14), Edge Distortion (13) and visible Light Masking Edge Flaws (13B), that can be simply weakened by inserting the non-specific Diffusion Element (4) into the light path of and retrofitting an Optical Light Masking Projector Assembly (20A), transforming the assembly into a Fade Out Optical Light Masking Projector Assembly (20F), causing a Diffused Illumination Zone Edge (12D) having reduced light masking technical difficulty as well as new visual results from the Fade Out Optical Light Masking Projector System (100) option.

An embodiment offers the option for a novel Fade Out Border (17) finishing with an outermost low light intensity Binary Illumination Zone Edge (12B) having a low light intensity edge reducing the visual impact caused by Edge Distortion (13) or Light Masking Edge Flaws (13B).

An embodiment can offer a method of eliminating unwanted visible Chromatic Aberration Particle (14D) from an Illumination Interior (15) on an Illumination Zone (10) for at least optical light masking projectors that utilize a Condensing Lens (5) or Glass Light Mask Plate (2B) by using non-specific Diffusion Element (4) within or forward the Gate Area (21) causing a possible Diffused Illumination Interior (15D). The possible Diffused Illumination Interior (15D) light is scattered and caused to blend together with scattered Chromatic Aberration Particle (14D) light so that the Chromatic Aberration Particle (14D) is not visible on a surface.

### One Embodiment of a Light Projecting System

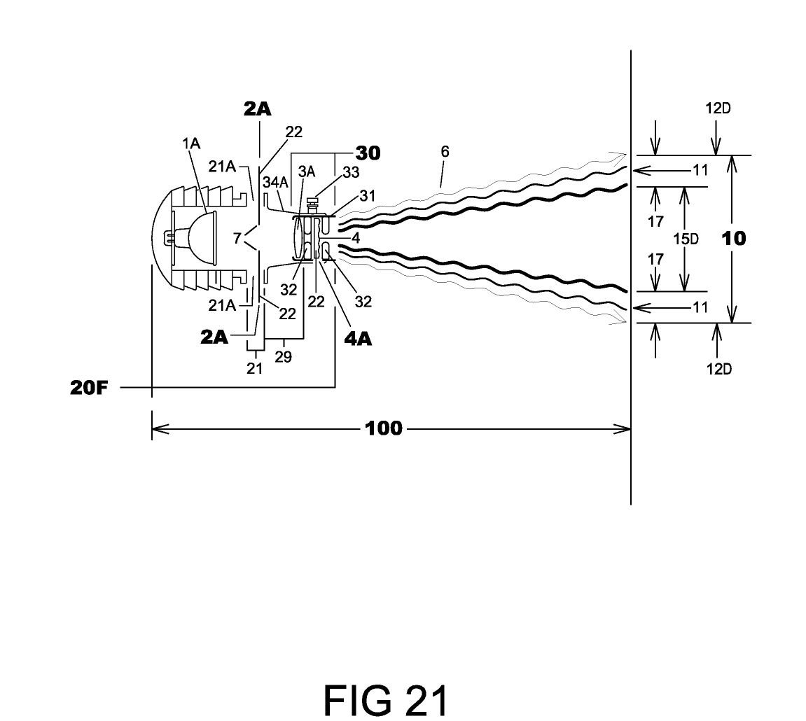

FIGS. 20 and 21 illustrate an embodiment of a light projecting system. The system includes a retrofit Diffusion Lens (4A) component form that has a transparent Plate (22) element with one external surface modified to scatter light through a slightly textured Diffusion Element (4) surface as a constituent part of the component form with the Diffusion Element (4) textured surface employing a total coverage Diffusion Element (4) design type as a means of scattering light from any striking point in combination with an optical light masking projector assembly with the Diffusion Element (4) positioned forward the Objective Focal Lens Area (29) within an optical light masking projector assembly.

FIG. 20 is an illustrative isometric drawing showing how an Optical Light Masking Projector Assembly (20A) is retrofitted to a Fade Out Optical Light Masking Projector Assembly (20F) by introducing a total coverage Diffusion Element (4) design type into the light path of the assembly. The Illumination Zone (10) includes, a fairly uniform Diffused Illumination Interior (15D) free of Visible Chromatic Aberration Particle (14D) surrounded by a Fade Out Border (17) free of a Visible Chromatic Aberration Border (14) with the Fade Out Border (17) finished by a surrounding low light intensity outermost novel Diffused Illumination Zone Edge (12D) perimeter fashioned to loosely conform with the Desired Illumination Edge (11) shape formed by an Opaque Light Masking Edge (7). The Fade Out Optical Light Masking Projector System (100) is inclusive of both the Fade Out Optical Light Masking Projector Assembly (20F) and the Illumination Zone (10) novel visual results.

FIG. 21 is a section drawing illustrating one embodiment of a retrofitted assembly, in more detail. A Diffusion Lens (4A) component form including a translucent Plate (22) element that has been made slightly translucent over the entire surface of one side with a total coverage Diffusion Element (4) design type as a constituent part of the component form to scatter light, with the Diffusion Element (4) positioned forward the Objective Focal Lens Area (29) within an Objective Focal Lens Assembly (30). The illustrative optical light masking projector assembly in FIG. 20 components are shown in FIG. 21 as a detailed assembly of components and FIG. 21 includes an Objective Focal Cone (31) that has been retrofitted to include a Diffusion Lens (4A) component form converting the FIG. 20 Optical Light Masking Projector Assembly (20A) portion to a Fade Out Optical Light Masking Projector Assembly (20F) by incorporating a Diffusion Lens (4A) component form.

The Diffusion Lens (4A) component form can be retrofitted into an Optical Light Masking Projector Assembly (20A) as with the option to include or not the Diffusion Lens (4A) component form during or after final adjustment of the Opaque Light Masking Edge (7) opening providing installation contractors and consumers the optional choice for the novel Fade Out Optical Light Masking Projector System (100) result or not

The Reflector Light Source (1A) causes a light path through the Gate Area (21) having Light Mask Retainer (21A) areas that serve to position Light Mask Shutters (2A) either radially along the light path axis and/or in and out perpendicular to the light path axis with the Light Masking Shutters (2A) including Light Masking Edges (7) where the Light Masking Edges (7) cause an opening that can be variable in size from small to large to shape light and the shaped light path travels through an Objective Focal Singlet Lens (3A) held into position by Clamp (32) inside of Objective Focal Cone (31) with the Objective Focal Cone (31) fit into a Straight Cone (34A) with the entire Objective Focal Lens Sub-Assembly (30) position either in-focus, slightly out-of focus, or completely out-of-focus and the Objective Focal Lens Sub-Assembly (30) locked into position by Locking Screw (33) with the Objective Focal Lens Sub-Assembly (30) retrofitted to include a Diffusion Lens (4A) component form with the Diffusion Lens (4A) component form positioned forward the Objective Focal Lens Area (29) either before or after final adjustment of the optical light masking projector with the Diffusion Lens (4A) component form held into position by a second Clamp (32) and with the Diffusion Lens (4A) component form including a translucent Plate (22) element and a Diffusion Element (4) as a constituent part of the component to scatter light, and with the Diffusion Element (4) constituent part causing the shaped Outbound Light Beam (6) light to scatter and illuminate a surface forming an Illumination Zone (10) with scattered shaped light controlled by an Opaque Light Masking Edge (7) and the scattered shaped light loosely conforming to a Desired Illumination Edge (11) and the scattered shaped light including a novel Diffused Illumination Zone Edge (12D) outermost lower light intense perimeter finishing a Fade Out Border (17) free of a visible Chromatic Aberration Border (14) with the novel Fade Out Border (17) including a light intensity tapering effect that increases in intensity approaching a greater light intensive Diffused Illumination Interior (15D) with the Diffused Illumination Interior (15D) having a fairly uniform light intensity and fairly flawless scattered illumination free of visible Chromatic Aberration Particle (14D) with all described including one of many possible combinations for a Fade Out Optical Light Masking Projector System (100).

This embodiment is not limited to the projector configuration shown nor limited to a single Objective Lens (3) and all projector configurations including those that utilize one or more Condensing Lenses (5) will offer the same Illumination Zone (10) results described in these embodiments.

Component Forms with Diffusion Element

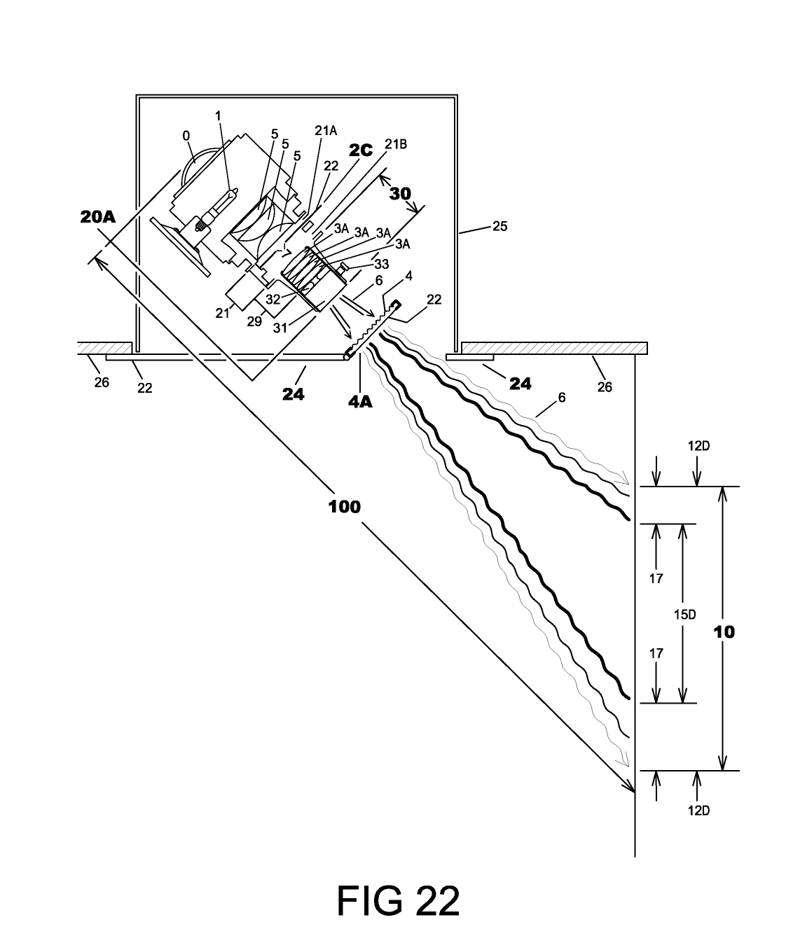

FIGS. 22-41 presented below demonstrate component forms of certain embodiments and are not meant to be limiting, but rather to illustrate a starting point.

FIG. 22 is a section drawing illustrating a recessed installation including an Optical Light Masking Projector Assembly (20A) recessed behind a Finished Surface Plane Of Structure (26) with the Optical Light Masking Projector Assembly (20A) installed within a Recessed Light Housing (25) designed to accept Trim Assembly (24) to cover the opening caused by Recessed Light Housing (25) in the Finished Surface Plane of Structure (26) with the Trim Assembly (24) including a trim Plate (22) element and an integral Diffusion Lens (4A) component form as part as part of Trim Assembly (24) with the Diffusion Lens (4A) component form including a Plate (22) element combined with a non-specific Diffusion Element (4) as a constituent part of the component to scatter light, and with the non-specific Diffusion Element (4) positioned in the light path of the Optical Light Masking Projector Assembly (20A) and shown to be placed forward the Gate Area (21) with the Diffusion Element (4) outside the optical light masking projector assembly causing the novel Fade Out Border (17) and Fade Out Optical Light Masking Projector System (100). The non-specific Diffusion Element (4) can be positioned anywhere within or forward the Gate Area (21) including outside of the Optical Light Masking Projector Assembly (20A) and the non-specific Diffusion Element (4) position and component form shown are not limited to being integral to a Trim Assembly (24).

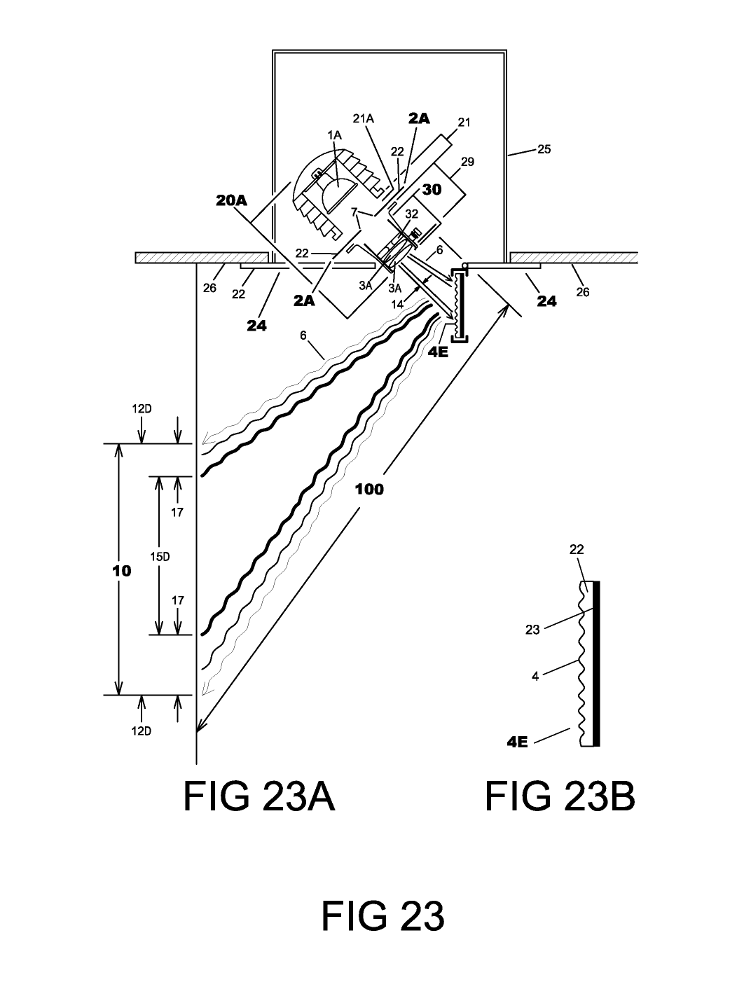

FIGS. 23A and 23B are section drawings illustrating the use of a Reflector With Integral Diffusion (4E) component form positioned outside of the Optical Light Masking Projector Assembly (20A). FIG. 23A demonstrates an application including the component form while FIG. 23B demonstrates in more detail the Reflector With Integral Diffusion (4E) component form applied to FIG. 23A.

FIG. 23A illustrates a recessed installation including the Optical Light Masking Projector Assembly (20A) recessed behind a Finished Surface Plane Of Structure (26) with the Optical Light Masking Projector Assembly (20A) installed within a Recessed Light Housing (25) designed to accept Trim Assembly (24) to cover the opening caused by Recessed Light Housing (25) in the Finished Surface Plane of Structure (26) with the Trim Assembly (24) including a trim Plate (22) element and an integral multi-function Reflector With Integral Diffusion (4E) component form as part of Trim Assembly (24) with the Reflector With Integral Diffusion (4E) component form including a Plate (22) element combined with a non-specific Diffusion Element (4) as constituent parts of the component to scatter light and a Reflective Surface (23) element as constituent part of the component to reflect light, and with the non-specific Diffusion Element (4) positioned in the light path of the Optical Light Masking Projector Assembly (20A) and placed forward the Gate Area (21) with the Reflector With Integral Diffusion (4E) component form positioned outside the optical light masking projector assembly causing a Fade Out Optical Light Masking Projector System (100). The Reflector With Integral Diffusion (4E) component form shown could also be positioned within or forward the Gate Area (21) including anywhere outside the Optical Light Masking Projector Assembly (20A) and the non-specific Diffusion Element (4) constituent part of the component form shown as well as the component itself are not limited to the position or component design shown, and the component form illustrated is therefore not limited to being integral to a Trim Assembly (24).

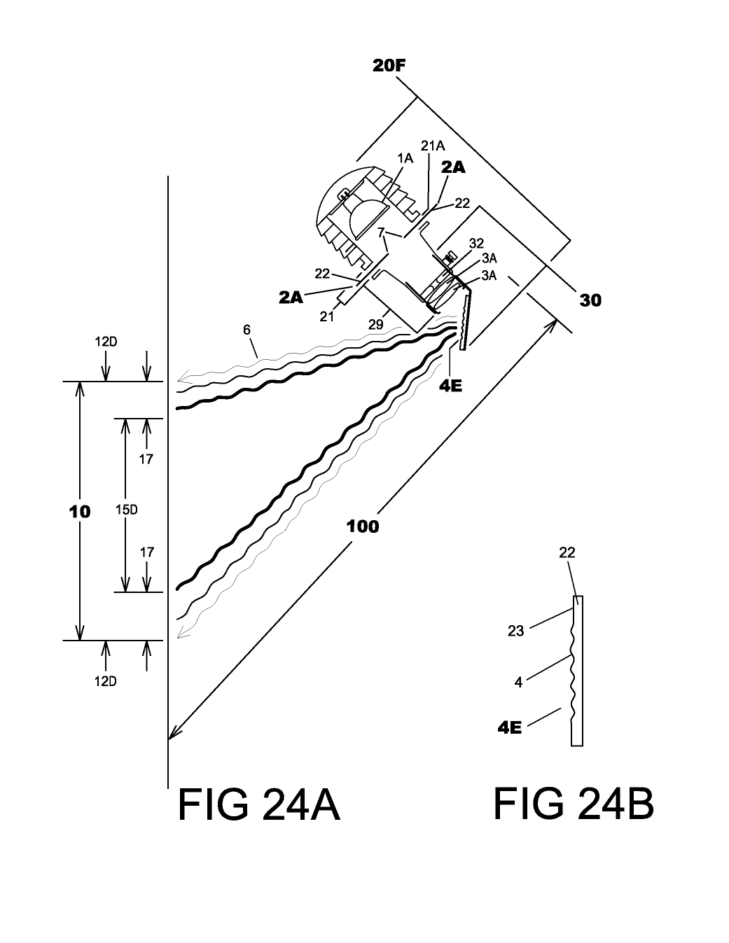

FIGS. 24A and 24B are section drawings illustrating the use of a Reflector With Integral Diffusion (4E) component form as being integral to a Fade Out Optical Light Masking Projector Assembly (20F). FIG. 24A demonstrates an application including the component form while FIG. 24B demonstrates in more detail the Reflector With Integral Diffusion (4E) component applied to FIG. 24A.

FIG. 24 illustrates the combination of a multi-function Reflector With Integral Diffusion (4E) component form including an opaque Plate (22) element having an integral Reflective Surface (23) element as constituent part of the component to reflect light, with the Reflective Surface (23) element and Plate (22) element modified to include a non-specific Diffusion Element (4) as constituent part of the component to scatter light, with the non-specific Diffusion Element (4) positioned forward the Gate Area (21) within an optical light masking projector assembly and causing a method to achieve a Fade Out Optical Light Masking Projector Assembly (20F) and Fade Out Optical Light Masking Projector System (100). The Reflector With Integral Diffusion (4E) component form shown could also be positioned within or forward the Gate Area (21) including anywhere outside of the Optical Light Masking Projector Assembly (20A), and the non-specific Diffusion Element (4) constituent part of the component form shown as well as the component itself are not limited to the position or component design shown, and the component form illustrated is therefore not limited to being integral to a Objective Focal Lens Sub-Assembly (30).

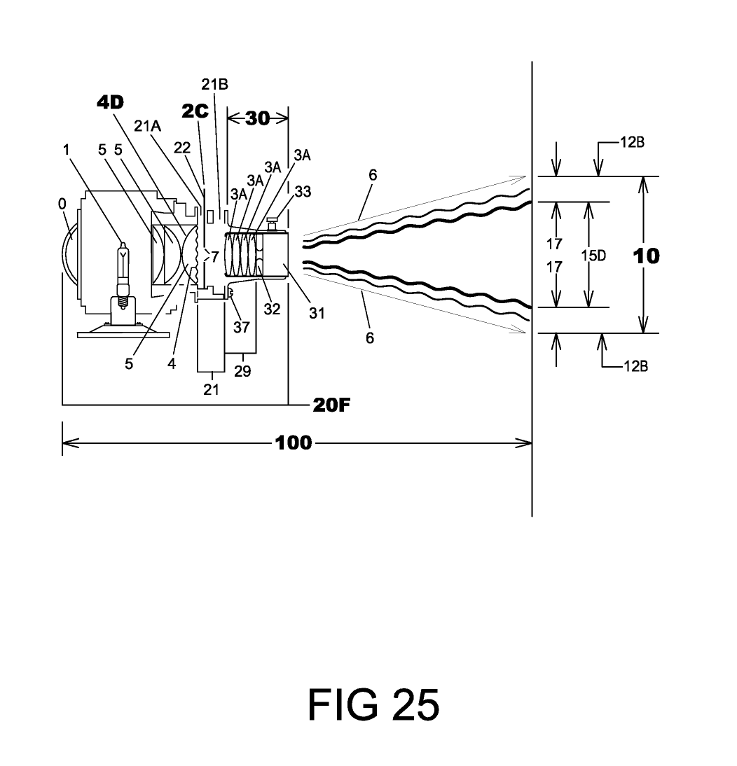

FIG. 25 is a section drawing illustrating the combination of a multi-function Condensing Lens With Integral Diffusion (4D) component form including a Condensing Lens (5) element combined with an integral non-specific Diffusion Element (4) as a constituent part of the component to scatter light, with the component positioned at the start of the Gate Area (21) of an optical light masking projector, producing a method for a Fade Out Optical Light Masking Projector Assembly (20F) and Fade Out Optical Light Masking Projector System (100).

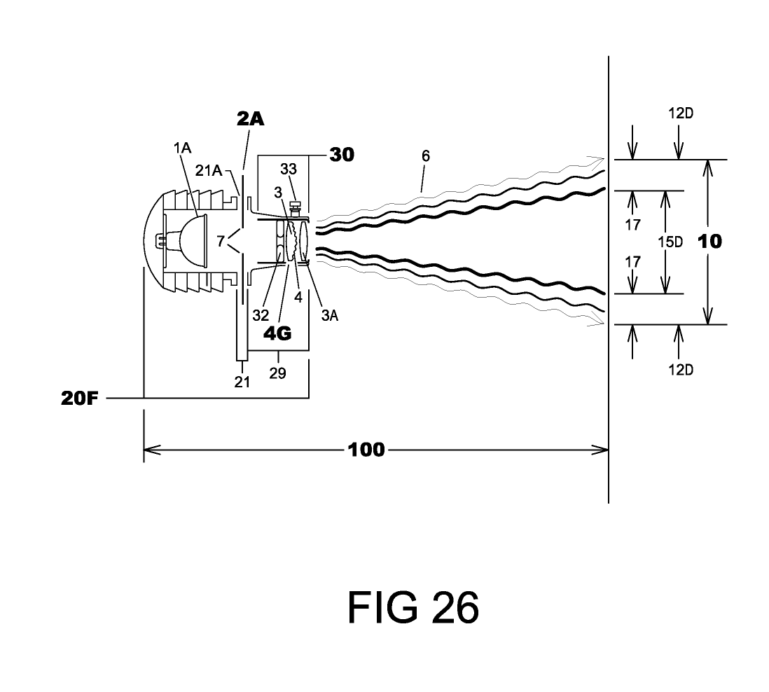

FIG. 26 is a section drawing illustrating a multi-function Objective Focal Lens With Integral Diffusion (4G) component form including an Objective Focal Lens (3) element combined with an integral non-specific Diffusion Element (4) as a constituent part of the component to scatter light, with the component positioned in the Objective Focal Lens Area (29) within an Objective Focal Lens Sub-Assembly (30) with the sub-assembly positioned within an optical light masking projector assembly, producing a method for a Fade Out Optical Light Masking Projector Assembly (20F) and Fade Out Optical Light Masking Projector System (100).

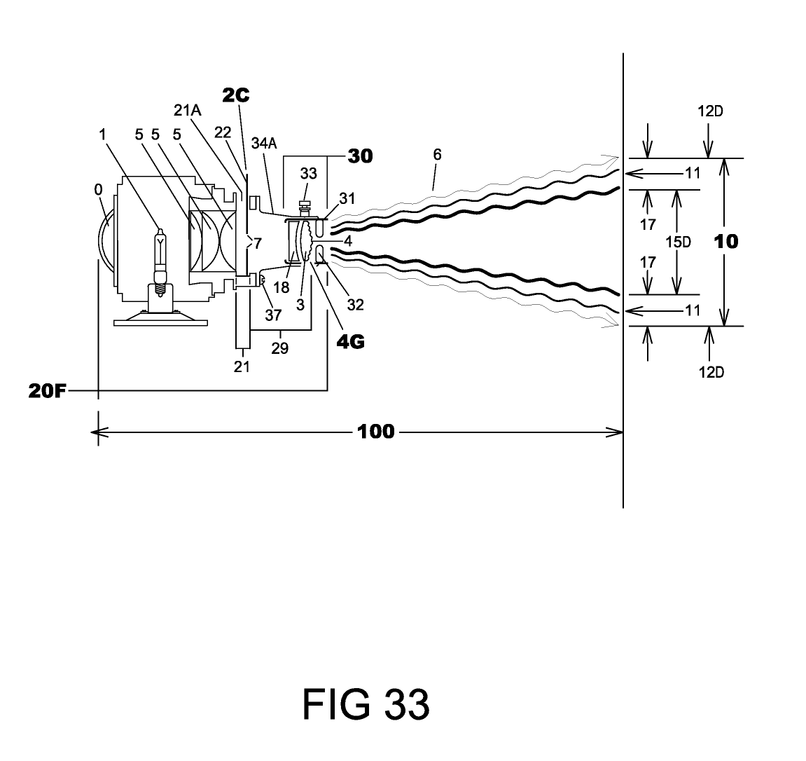

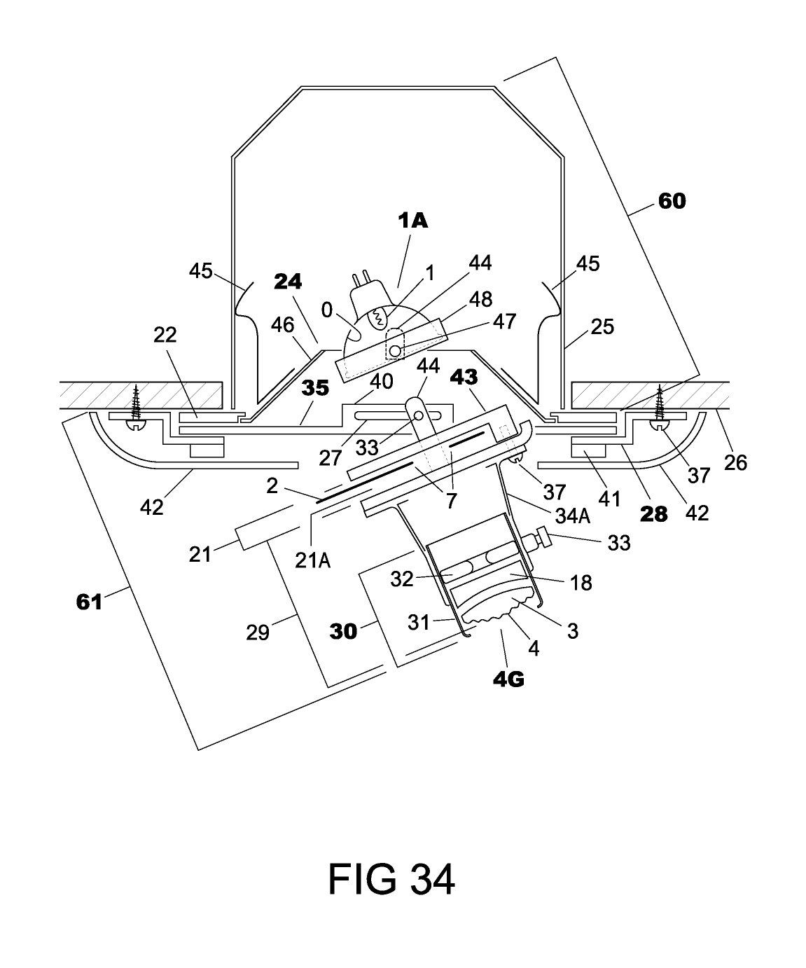

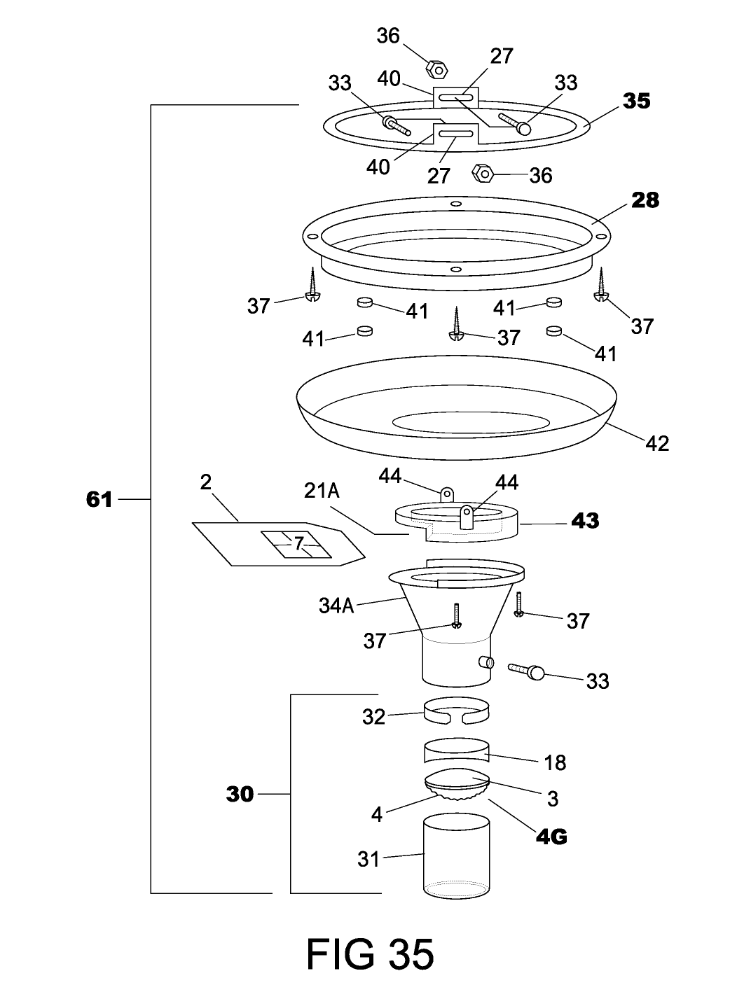

The Objective Focal Lens With Integral Diffusion (4G) component form can be positioned anywhere within the Objective Focal Lens Area (29) with the Objective Focal Lens Area (29) including an area outside of an optical light masking projector assembly, and furthermore, the non-specific Diffusion Element (4) constituent part of the component form shown as well as the component itself are not limited to being inclusive to an optical light masking projector assembly as shown in FIGS. 34 and 35, and the component form illustrated could include either a singlet lens element type or in combination with a Corrective Lens Element (18) type to form an achromatic lens component as shown in FIGS. 33, 34 and 35 with either one of the lens element types when combined to include an integral non-specific Diffusion Element (4) as a constituent part of the lens will produce an Objective Focal Lens With Integral Diffusion (4G) component form and method for a Fade Out Optical Light Masking Projector system (100) with the non-specific component forms representing the starting point for application of the described embodiments.

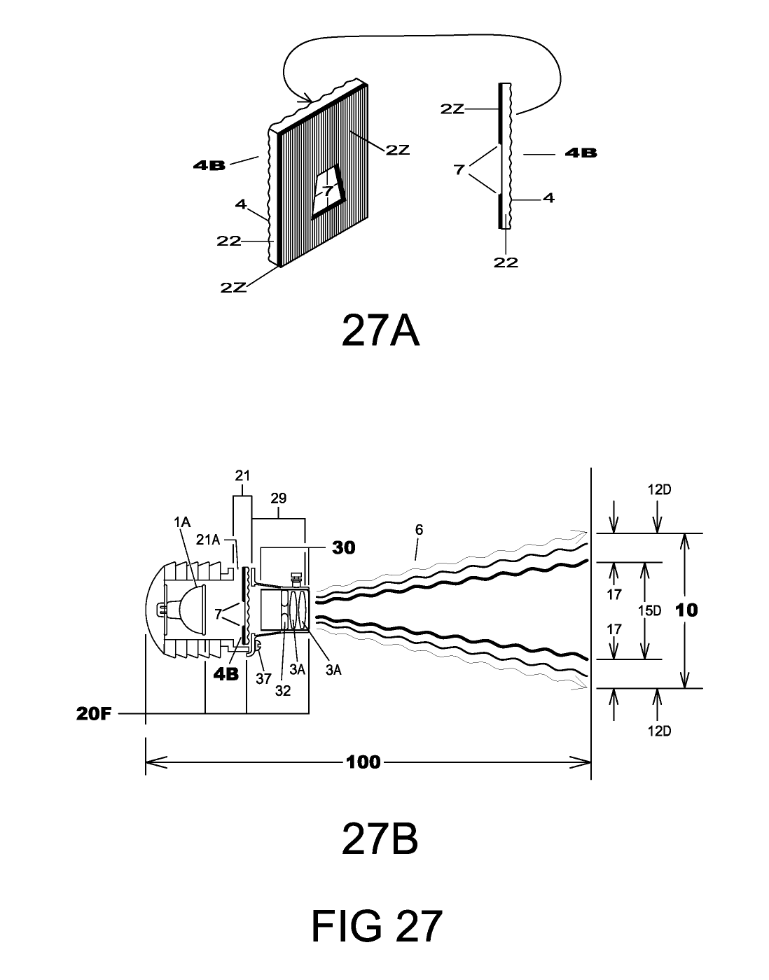

FIGS. 27A and 27B Illustrate a multi-function novel Translucent Light Mask Plate With Integral Diffusion (4B) component form, for use in the Gate Area (21) of an optical light masking projector, with the component including a Plate (22) element, a non-specific Diffusion Element (4) as constituent part of the component to scatter light, and a Light Blocking Material (2Z) element layer for the component to block light, where the Light Blocking Material (2Z) element layer can be fabricated or field modified to include an Opaque Light Masking Edge (7) opening element to shape light.

FIG. 27A includes a sectional drawing and a rotated isometric view illustrating a multi-functional novel Translucent Light Mask Plate With Integral Diffusion (4B) component form with the component including an area where the Light Blocking Material (2Z) element layer is absent to form an Opaque Light Masking Edge (7) opening element and where both the Opaque Light Masking Edge (7) element and the non-specific Diffusion Element (4) combined are capable of shaping and scattering light when in combination with an optical light masking projector.

FIG. 27B is a sectional drawing illustrating the combination of a novel Translucent Light Mask Plate With Integral Diffusion (4B) component form positioned within the Gate Area (21) of an optical light masking projector, and when combined teaching a method to decrease the difficulty of fashioning an Opaque Light Masking Edge (7) through a Fade Out Optical Light Masking Projector Assembly (20F), with the component form including an area where the Light Blocking Material (2Z) element is absent to form an Opaque Light Masking Edge (7) opening that provides an unblocked path of shaped light that is scattered by the non-specific Diffusion Element (4) constituent part of the component and causing an Illumination Zone (10) to include the Fade Out Border (17) with all forming a Fade Out Optical Light Masking Projector System (100).

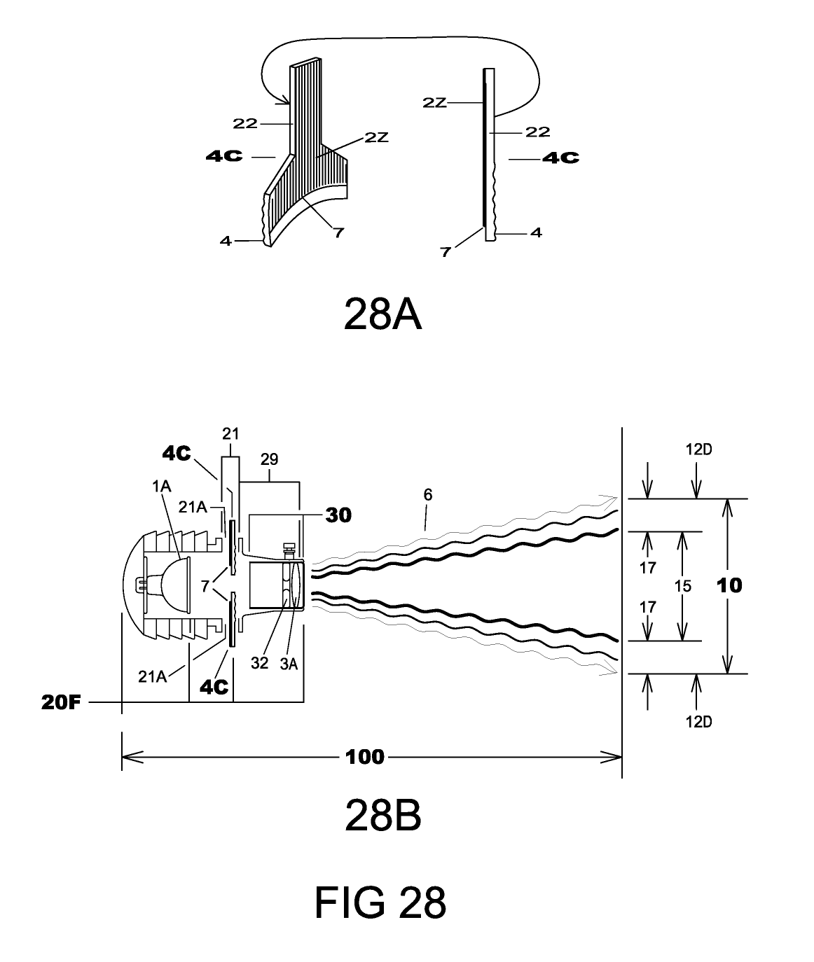

FIGS. 28A and 28B Illustrate a novel Translucent Light Mask Shutter(s) With Integral Diffusion (4C) component form, for use in the Gate Area (21) of an optical light masking projector, with the component including a Plate (22) element, a non-specific Diffusion Element (4) as constituent part of the component to scatter light, and a Light Blocking Material (2Z) element layer for the component to block light, where the Light Blocking Material (2Z) element layer can be fabricated or field modified to include an Opaque Light Masking Edge (7) element to shape light.

FIG. 28A includes a sectional drawing and a rotated isometric view illustrating the multi-functional Translucent Light Mask Shutter With Integral Diffusion (4C) component form with the component including a Light Blocking Material (2Z) element layer over the upper portion of Plate (22) and covering an area down to and causing an Opaque Light Masking Edge (7) element leaving the remaining non-specific Diffusion Element (4) constituent part lower area of the component at least partially translucent to scatter light where both the Opaque Light Masking Edge (7) element and the non-specific Diffusion Element (4) combined are capable of shaping and scattering light when in combination with an optical light masking projector.

FIG. 28B is a sectional drawing illustrating the combination of the Translucent Light Mask Shutters With Integral Diffusion (4C) component forms positioned within the Gate Area (21) of an optical light masking projector, and when combined teaching a novel method to decrease the difficulty of fashioning an Opaque Light Masking Edge (7) through a Fade Out Optical Light Masking Projector Assembly (20F), with each of the component forms including an area where the Light Blocking Material (2Z) element is absent to cause an Opaque Light Masking Edge (7) and each of the component forms including an exposed unblocked non-specific Diffusion Element (4) area, and when multiple novel Translucent Light Mask Shutters With Integral Diffusion (4C) component forms are adjusted within Light Mask Retainers (21A) either radially along the light path axis and/or in and out perpendicular to the light path axis form an Opaque Light Masking Edge (7) opening and path of unblocked shaped light that is scattered by the non-specific Diffusion Element (4) constituent part of the component and causing an Illumination Zone (10) to include the novel Fade Out Border (17) with all forming a Fade Out Optical Light Masking Projector System (100).

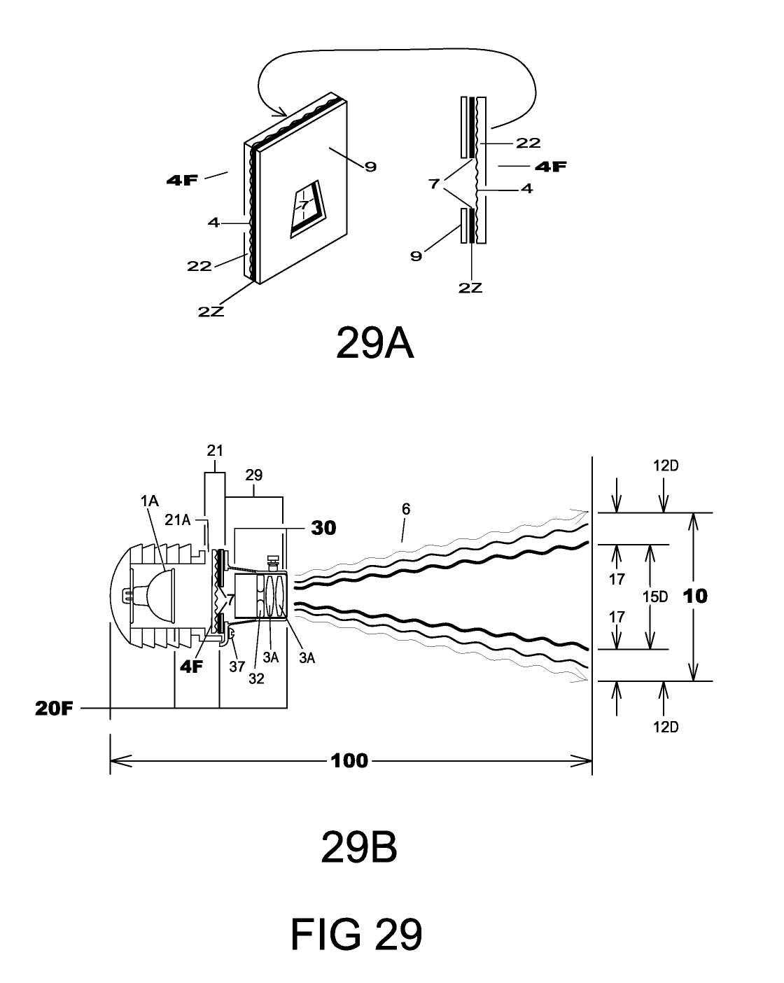

FIGS. 29A and 29B Illustrate a multi-function novel Photosensitized Translucent Light Mask Plate With Integral Diffusion (4F) component form, for use in the Gate Area (21) of an optical light masking projector, with the component including a Plate (22) element, a non-specific Diffusion Element (4) as constituent part of the component to scatter light, a Light Blocking Material (2Z) element layer for the component to block light, a Photosensitized Layer (9) element to photograph the shape of a target to be illuminated, where the Light Blocking Material (2Z) element layer can be modified to include an Opaque Light Masking Edge (7) opening element that shapes light after having photographed the target to be illuminated.

FIG. 29A includes a sectional drawing and a rotated isometric view illustrating a multi-functional novel Photosensitized Translucent Light Mask Plate With Integral Diffusion (4F) component form with the component including an area where the Photosensitized Layer (9) and the Light Blocking Material (2Z) element layer have been removed after having photographed the target to be illuminated, with the area absent of the Light Blocking Material (2Z) element layer forms an Opaque Light Masking Edge (7) opening element and where both the Opaque Light Masking Edge (7) element and the non-specific Diffusion Element (4) constituent part combined are capable of shaping and scattering light when in combination with an optical light masking projector.

FIG. 29B is a sectional drawing illustrating the combination of a novel Photosensitized Translucent Light Mask Plate With Integral Diffusion (4F) component form positioned within the Gate Area (21) of an optical light masking projector, and when combined teaching a novel method to decrease the difficulty of fashioning an Opaque Light Masking Edge (7), with the component form including an area where the Photosensitized Layer (9) and the Light Blocking Material (2Z) element layer have been removed after having photographed the target to be illuminated, with the area absent of the Light Blocking Material (2Z) element layer forms an Opaque Light Masking Edge (7) opening that provides an unblocked path of shaped light that is scattered by the non-specific Diffusion Element (4) constituent part of the component and causing an Illumination Zone (10) to include the novel Fade Out Border (17) with all forming a Fade Out Optical Light Masking Projector System (100). Since optical light masking projectors operate at high temperatures, the Photosensitized Layer (9) will degrade and therefore needs to be removed (not shown) prior to operating the optical projector for a long period of time, and by removing the Photosensitized Layer (9) changes the Photosensitized Translucent Light Mask Plate With Integral Diffusion (4F) component form into a Translucent Light Mask Plate With Integral Diffusion (4B) component form.

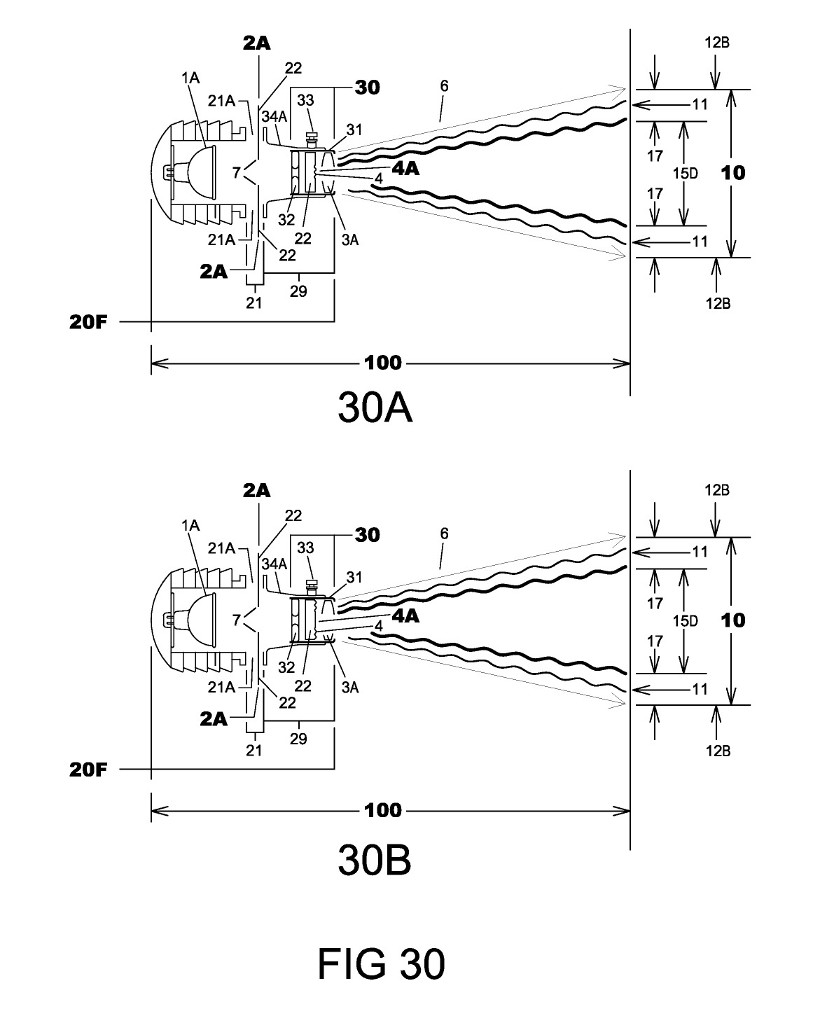

FIGS. 30A and 30B are sectional drawings illustrating Diffusion Lens (4A) component forms including a Plate (22) element combined with a Diffusion Element (4) as a constituent part of the component forms to scatter light where FIG. 30A implements a center Diffusion Element (4) design type and FIG. 30B implements a peripheral Diffusion Element (4) design type with the component forms positioned in the Objective Focal Lens Area (29) within an Objective Focal Lens Sub-Assembly (30) sometimes having to be in-focus and other times having to be out-of-focus and with the Objective Focal Lens Sub-Assemblies (30) positioned within an optical light masking projector assembly and demonstrating methods for Fade Out Optical Light Masking Projector Assemblies (20F) delivering an Outbound Light Beam (6) shaped by Light Masking Edges (7) causes an Illumination Zone (10) to include a Fade Out Border (17) tapering light intensity free of a visible Chromatic Aberration Border (14) sometimes finishing with a low light intensity outermost Binary Illumination Zone Edge (12B) perimeter and causing a Fade Out Optical Light Masking Projector System (100).

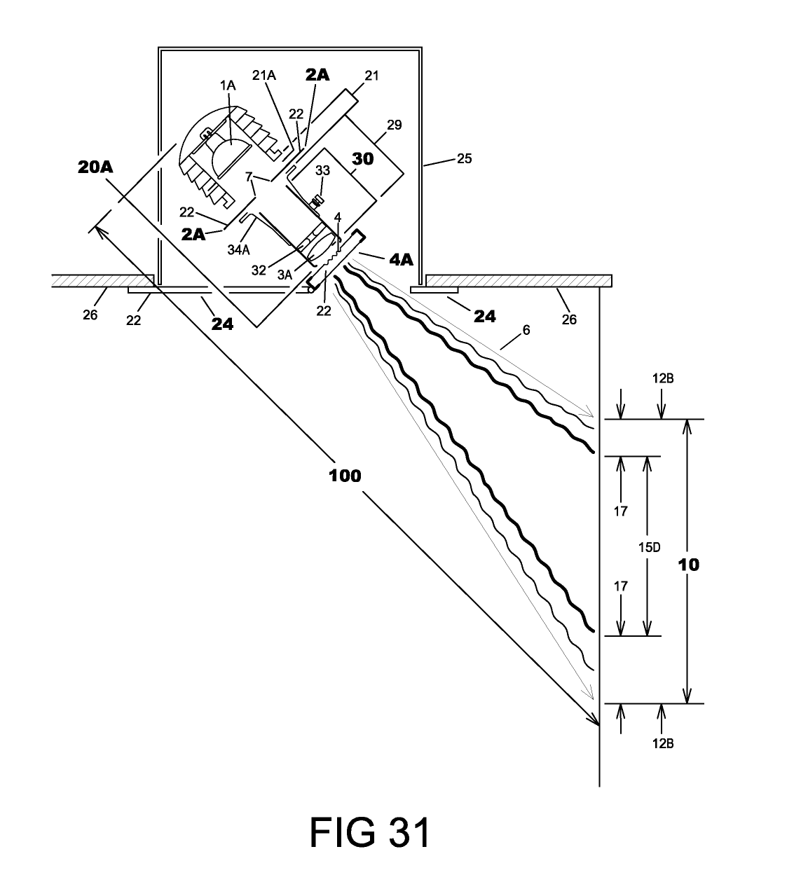

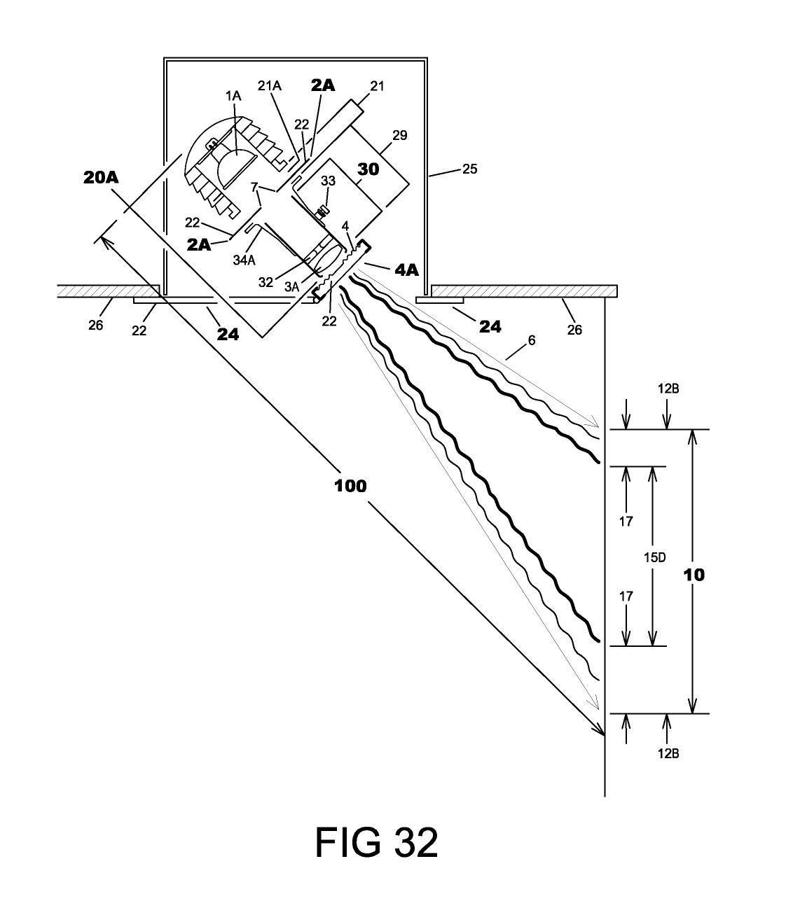

FIGS. 31 and 32 are sectional drawings illustrating Diffusion Lens (4A) component forms including a Plate (22) element combined with a Diffusion Element (4) as a constituent part of the component forms to scatter light where FIG. 31 implements a center Diffusion Element (4) design type and FIG. 32 implements a peripheral Diffusion Element (4) design type with the component forms positioned forward the Objective Focal Lens Area (29) and outside of an optical light masking projector with said projectors including an Objective Focal Singlet Lens (3A) sometimes having to be in-focus and other times having to be out-of-focus with said projectors delivering an Outbound Light Beam (6) shaped by Light Masking Edges (7) and when said light beam transmits through the Diffusion Element (4) causes light to scatter and form an Illumination Zone (10) to include a Fade Out Border (17) tapering light intensity free of a visible Chromatic Aberration Border (14) sometimes finishing with a low light intensity outermost Binary Illumination Zone Edge (12B) perimeter and causing a Fade Out Optical Light Masking Projector System (100).

FIG. 33 is a sectional drawing illustrating a non-specific component form where an Objective Focal Lens with Integral Diffusion (4G) component form has the option to be achromatic or not providing non-specific variable component forms. An Objective Focal Lens With Integral Diffusion (4G) component form including an Objective Focal Lens (3) element and an integral non-specific Diffusion Element (4) as a constituent part of the component form to scatter light, has the option to be combined with a Corrective Lens Element (18) to cause a different component form being achromatic. A Corrective Lens Element (18) separate from an Objective Focal Lens With Integral Diffusion (4G) can be positioned within an Objective Focal Lens Sub-Assembly (30) and retained adjacent to one another by Clamp (32) to cause an optional achromatic Objective Focal Lens With Integral Diffusion (4G) component form positioned in the Objective Focal Lens Area (29) within an optical light masking projector, producing a method for a Fade Out Optical Light Masking Projector Assembly (20F) and Fade Out Optical Light Masking Projector System (100). The non-specific Diffusion Element (4) shown in FIG. 33 is by way of example and not by way of limiting the option for the Corrective Lens Element (18) to carry the Diffusion Element (4) instead of the Objective Focal Lens (3) element.

FIG. 34 is a section drawing illustrating an optical light masking projector retrofit for converting a recessed light into a Fade Out Optical Light Masking Projector System (100) with the conversion formed from two or more separate independent sub-assemblies joined by only a light path. Rear Sub-Assembly (60) includes a Light Source (1) while Front Sub-Assembly (61) includes the Light Mask (2) and Objective Focal Lens (3) and neither independent sub-assembly alone includes the three essential basic components necessary to cause an optical light masking projector assembly. Rear Sub-Assembly (60) is independent and not mechanically joined to Front Sub-Assembly (61) and therefore neither of the two sub-assemblies alone are optical light masking projector assemblies but when joined by a light path form an optical light masking projector.

Rear Sub-Assembly (60) shown in FIG. 34 is an independent recessed light and the Front Sub-Assembly (61) independently adds the additional essential basic components necessary for an optical light masking projector retrofit and when the two are joined by a light path cause an optical light masking projector without mechanically attaching the two sub-assemblies together.

Rear Sub-Assembly (60) shown in FIG. 34 includes a Recessed Light Housing (25) designed to accept Trim Assembly (24) to cover the opening caused by Recessed Light Housing (25) in the Finished Surface Plane Of Structure (26) with Trim Assembly (24) including a Plate (22) joined to Tapered Cone (46) with Tapered Cone (46) including a Mounting Tab (44) to retain Lamp Holder Ring (48) using a Pivot Rivet (47) providing Lamp Holder Ring (48) the ability to rotate for vertical adjustment of the Integrated Reflector Light Source (1A) and the Trim Assembly (24) further including Trim Springs (45) that mechanically attach the Trim Assembly (24) to the Recessed Light Housing (25).

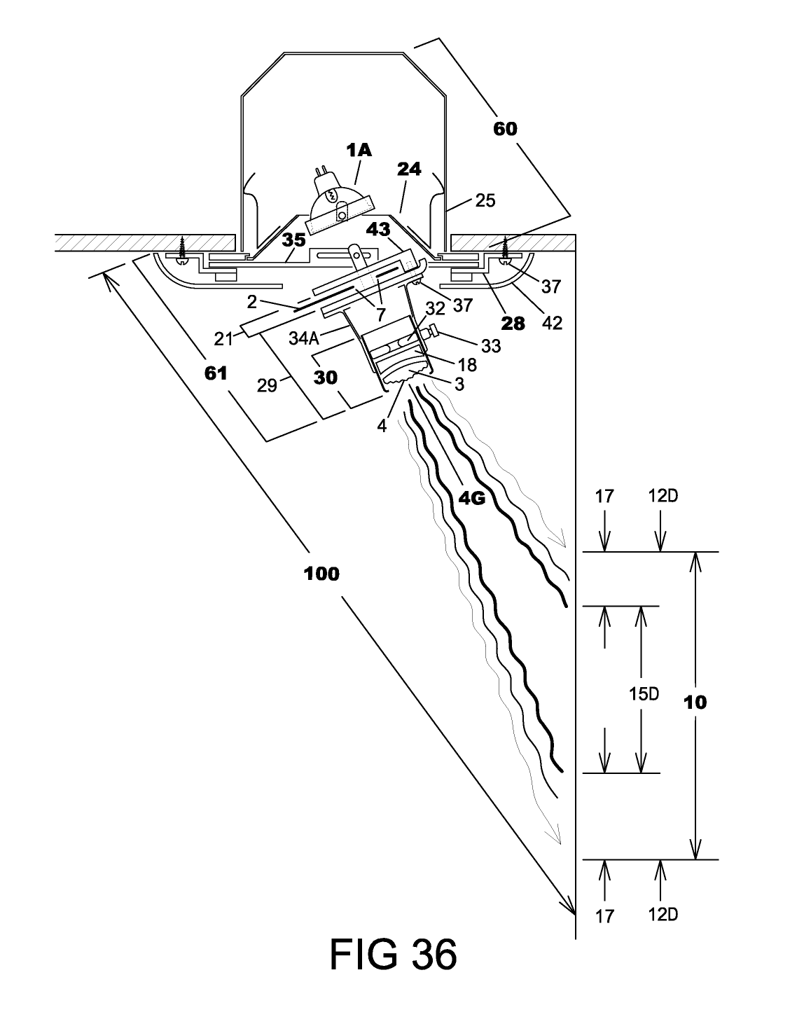

Front Sub-Assembly (61) shown in FIG. 34 is also shown as an isometric component assembly drawing in FIG. 35 and shown as a sectional system drawing in FIG. 36 and Front Sub-Assembly (61) includes the additional essential components necessary for an optical light masking projector retrofit to convert a recessed light into a Fade Out Optical Light Masking Projector System (100) with the Front Sub-Assembly (61) including a Conversion Mounting Bracket (28) that is independent of Rear Sub-Assembly (60) and said Conversion Mounting Bracket (28) is fastened to the Finished Surface Plane Of Structure (26) using Screws (37) with Conversion Mounting Bracket (28) including attached Finish Trim Retainer Magnets (41) to retain Finish Trim (42) with Conversion Mounting Bracket (28) designed to accept an Annular Flange (35) with said Annular Flange (35) including Annular Flange Ears (40) including Horizontal Adjustment Slots (27) designed to receive and align Gate Ring (43) into the light path axis and Gate Ring (43) including Mounting Tabs (44) with said Mounting Tabs (44) fastened to the Horizontal Adjustment Slots (27) using Locking Screws (33) and Slider Nuts (36) providing a pivot for vertical adjustment into the light path axis and said Gate Ring (43) including Light Mask Retainer(s) (21A) to retain Light Mask(s) (2) and said Gate Ring (43) designed to accept either a Straight Cone (34A) shown or a Periscope Cone (34B) not shown in the figure with said cone receiving an Objective Focal Cone Sub-Assembly (30) retained into position by Locking Screw (33) with said Focal Cone Sub-Assembly (30) including a non-specific Diffusion Element (4) as a constituent part of a non-specific component form to scatter light and cause an Illumination Zone (10) to include a Fade Out Border (17) free of a visible Chromatic Aberration Border (14) with all combined forming a Fade Out Optical Light Masking Projector System (100) by way of example and not by way of limiting the component forms or assemblies shown.

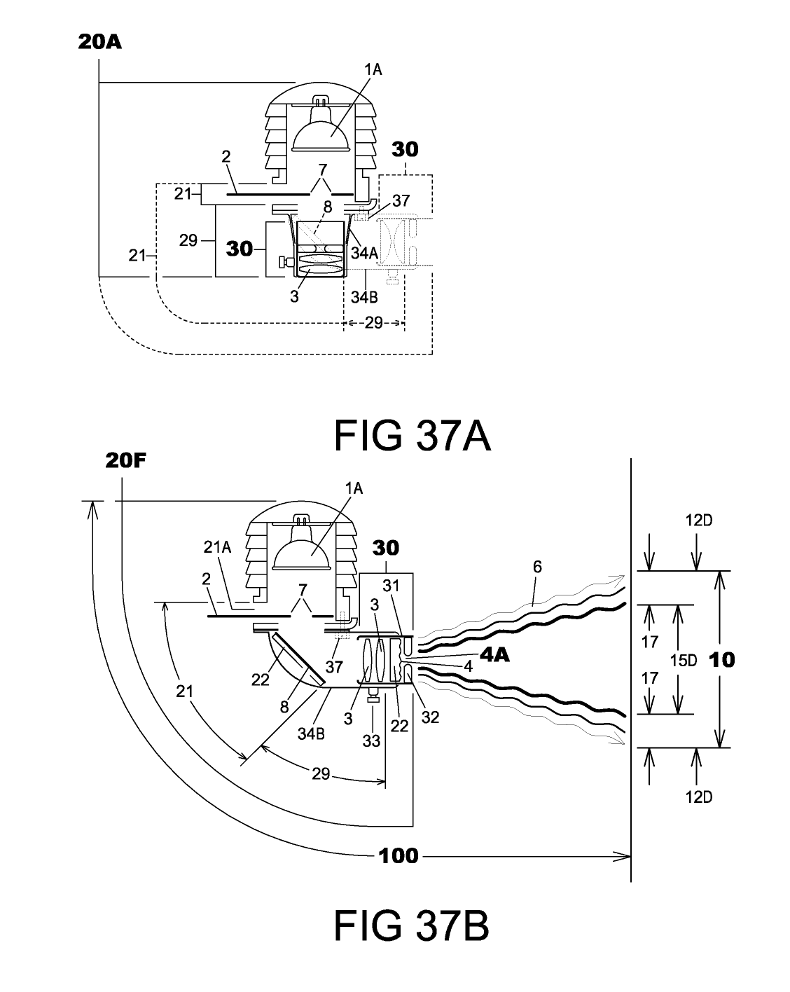

FIGS. 37A and 37B are section drawings illustrating how an Optical Light Masking Projector Assembly (20A) utilizing a Straight Cone (34A) shown by solid lines in FIG. 37A can be retrofitted with a Periscope Cone (34B) shown by dashed lines in FIG. 37A when Periscope Cone (34B) includes a Secondary Reflector (8). Dashed line Screw(s) (37) shown in either figures are 90 degrees off of actual position for clarity and retain either the Straight Cone (34A) or the Periscope Cone (34B). FIG. 37A shows the Periscope Cone (34B) as dashed lines with the Secondary Reflector (8) positioned in the Gate Area (21) while the Straight Cone (34A) shown by solid lines is positioned within the Objective Focal Lens Area (29). FIG. 37B illustrates the Periscope Cone (34B) retaining a Secondary Reflector (8) in the Gate Area (21) and also retaining an Objective Focal Lens Sub-Assembly (30) in the Objective Focal Lens Area (29) with the Objective Focal Cone (31) retrofitted to include a Diffusion Lens (4A) component form including a Plate (22) element and non-specific Diffusion Element (4) constituent part of the component form to scatter light converting the Optical Light Masking Projector Assembly (20A) shown in FIG. 37A into a Fade Out Optical Light Masking Projector Assembly (20F) shown in FIG. 37B to cause an Illumination Zone (10) to include a Fade Out Border (17) free of a visible Chromatic Aberration Border (14) and method for a Fade Out Optical Light Masking Projector System (100). The non-specific Diffusion Element (4) constituent part of a component form can be positioned anywhere within or forward the Gate Area (21) and therefore it's position as well as the component form shown are by way of example and not by way of limiting the component form type or position.

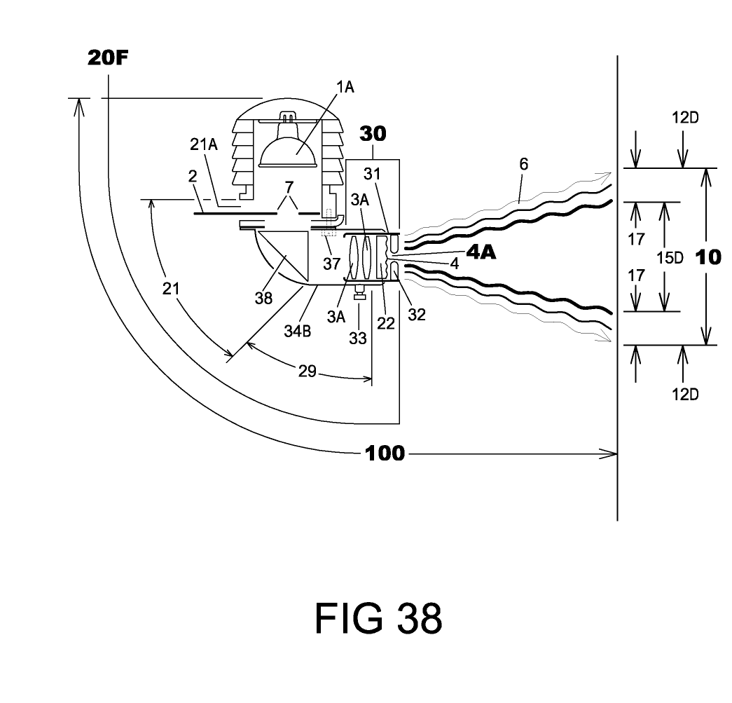

FIG. 38 is a sectional drawing illustrating an optical light masking projector including a Prism (38) positioned in the Gate Area (21) within a Periscope Cone (34B) retaining an Objective Focal Lens Sub-Assembly (30) retrofitted to include a Diffusion Lens (4A) component form including a Plate (22) element and non-specific Diffusion Element (4) as a constituent part of the component form to scatter light, converting an optical light masking projector into a Fade Out Optical Light Masking Projector Assembly (20F) causing an Illumination Zone (10) to include a Fade Out Border (17) free of a visible Chromatic Aberration Border (14) and method for a Fade Out Optical Light Masking Projector System (100). The non-specific Diffusion Element (4) constituent part of the component form can be positioned anywhere within or forward the Gate Area (21) and therefore it's position as well as the component form shown are by way of example and not by way of limiting the component form type or position.

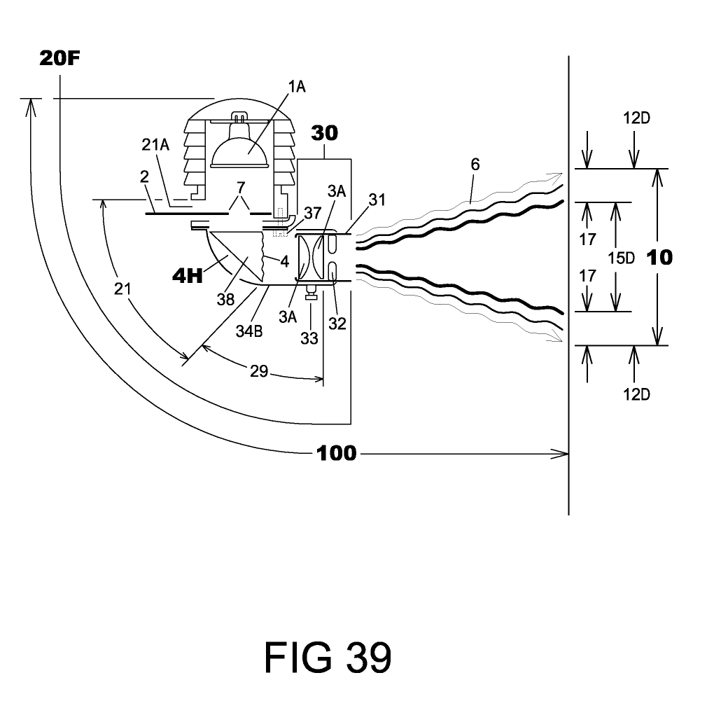

FIG. 39 is a sectional drawing illustrating the combination of a multi-function Prism With Integral Diffusion (4H) component form including a Prism (38) element combined with a an integral non-specific Diffusion Element (4) as a constituent part of the component form to scatter light, with the component form positioned within the Gate Area (21) within a Periscope Cone (34B) of an optical light masking projector assembly, producing a method for a Fade Out Optical Light Masking Projector Assembly (20F) and Fade Out Optical Light Masking Projector System (100).

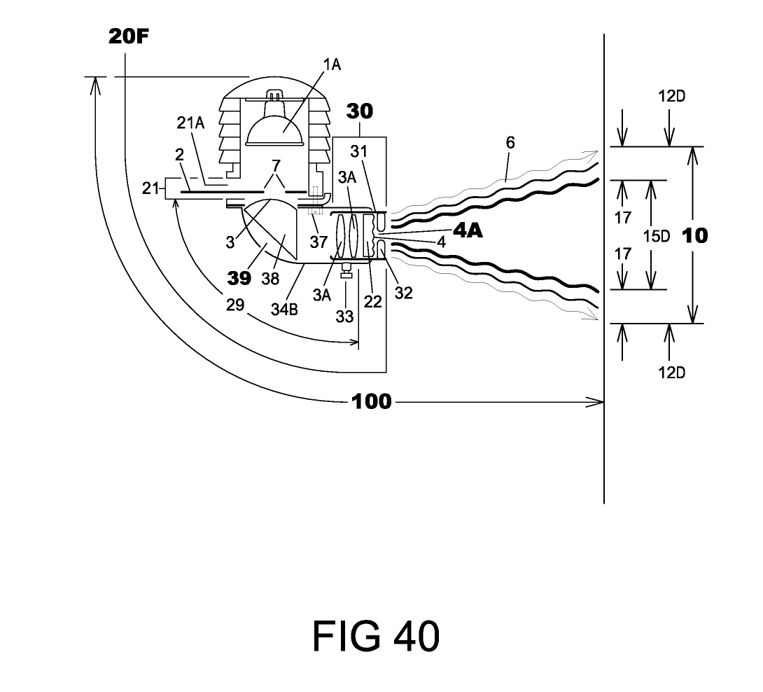

FIG. 40 is a sectional drawing illustrating a Prism With Integral Objective Focal Lens (39) component including a Prism (38) element and Objective Focal Lens (3) surface element with said component positioned in the Objective Focal Lens Area (29) within a Periscope Cone (34B) retaining an Objective Focal Lens Sub-Assembly (30) retrofitted to include a Diffusion Lens (4A) component form including a Plate (22) element and non-specific Diffusion Element (4) as a constituent part of the component form to scatter light and converting an optical light masking projector into a Fade Out Optical Light Masking Projector Assembly (20F) causing an Illumination Zone (10) to include a Fade Out Border (17) free of a visible Chromatic Aberration Border (14) and method for a Fade Out Optical Light Masking Projector System (100). The non-specific Diffusion Element (4) constituent part of said component form can be positioned anywhere within or forward the Gate Area (21) and therefore it's position as well as said component form shown are by way of example and not by way of limiting the component form type or position.

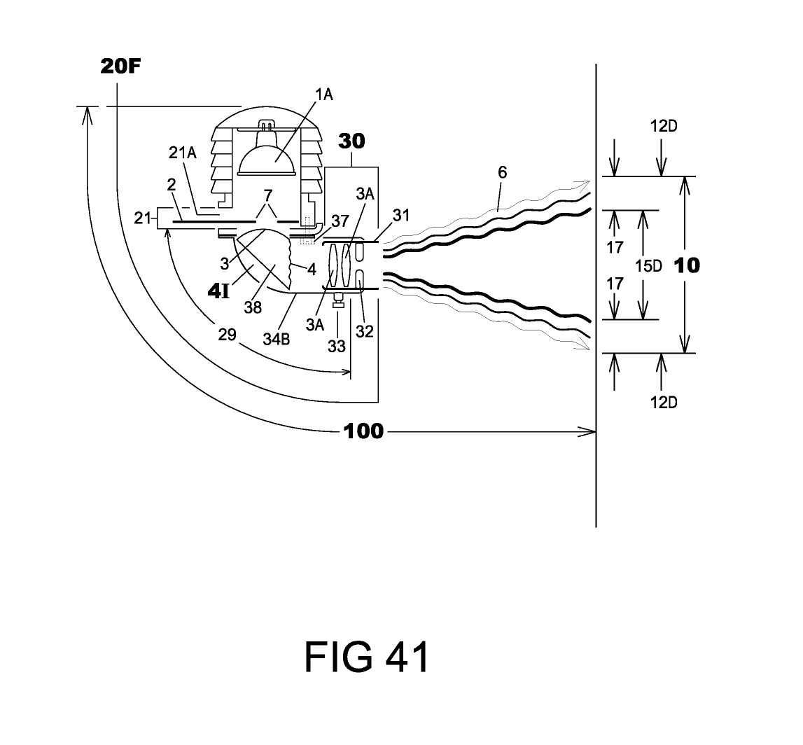

FIG. 41 is a sectional drawing illustrating the combination of a multi-function Prism With Integral Objective Focal Lens And Integral Diffusion (4H) component form including a Prism (38) element, an integral Objective Focal Lens (3) surface element and an integral non-specific Diffusion Element (4) as a constituent part of the component form to scatter light, with the component form positioned within the Objective Focal Lens Area (29) within a Periscope Cone (34B) of an optical light masking projector assembly, producing a method for a Fade Out Optical Light Masking Projector Assembly (20F) and Fade Out Optical Light Masking Projector System (100).

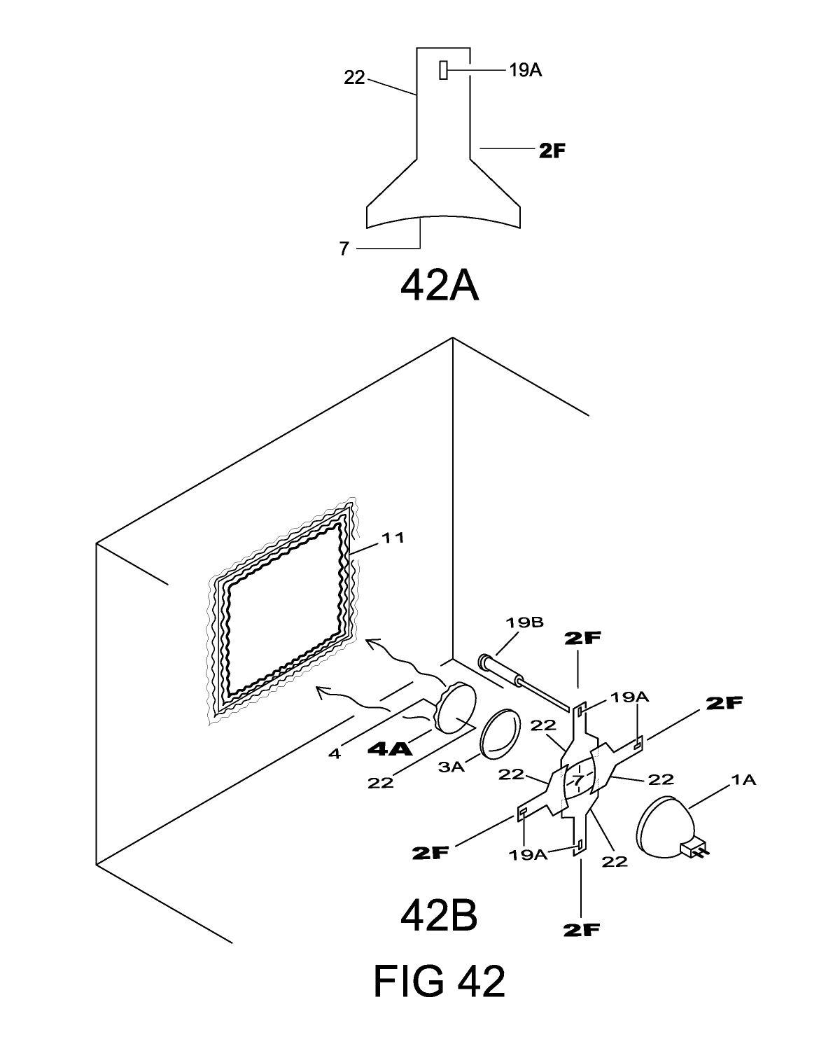

FIG. 42A and FIG. 42B illustrate a novel Light Mask Shutter With Adjustment Tool Slot (2F) component. Optical light masking projector assemblies operate at very high scorching temperatures, making it extremely difficult for installation contractors to adjust Light Masking Shutters (2A) either radially along the light path axis and/or in and out perpendicular to the light path axis. Extreme precision is required to align a light mask shutter's Opaque Light Masking Edge (7) to follow a desired Illumination Edge (11), and is especially difficult when a slight touch or slight tap on a hot Light Mask Shutter (2A) goes exponentially a long way in causing a visible Light Masking Edge Flaw (13B) miss-alignment especially when shaping a Binary Illumination Zone Edge (12B). The Light Mask Shutter With Adjustment Tool Slot (2F) provides a new method for adjusting a hot light masking shutter when shaping the Illumination Zone (10) having either a Binary Illumination Zone Edge (12B) or the novel Diffused Illumination Zone Edge (12D).

FIG. 42A is an elevation drawing illustrating the Light Mask Shutter With Adjustment Tool Slot (2F) component including of a Plate (22) element, a Tool Slot (19A), and an Opaque Light Masking Edge (7) element for use with an optical light masking projector.

FIG. 42B is an isometric drawing illustrating use of a Shutter Adjustment Tool (19B) to be inserted into Shutter Tool Slot (19A) element so that an installation contractor can adjust the hot Light Mask Shutter With Adjustment Tool Slot (2F) component form either radially along the light path axis and/or in and out perpendicular to the light path axis when the shutter is located within the not shown Gate Area (21) of an optical light masking projector without touching the hot shutter with their hands. The Shutter Tool Slot (19A) element can be implemented into a light mask shutter component of any shape, design or composition and therefore is not limited to the figures shown.

Combinations for a Total Coverage Diffusion Element Design Type

Regardless of an optical light masking projector configuration including with or without a Condensing Lens (5), and depending on an Objective Focal Lens Sub-Assembly (30) focus, in combination with a total coverage Diffusion Element (4) design type inclusive of possible variation such as graduation or pattern(s), with the total coverage Diffusion Element (4) design type as a constituent part of a non-specific component form of any composition fabrication or modification method positioned within or forward the Gate Area (21) including outside of an optical light masking projector assembly, the Illumination Zone (10) includes at least one visual result when in combination with either a normal or small Opaque Light Masking Edge (7) opening.

The total coverage Diffusion Element (4) design type in combination with either a normal or small Opaque Light Masking Edge (7) opening can cause the Illumination Zone (10) to sometimes include a novel Fade Out Border (17) free of a visible Chromatic Aberration Border (14) finishing with a low light intensity novel Diffused Illumination Zone Edge (12D) with Diffusion Element (4) positioned either, within the Gate Area (21), within the Objective Focal Lens Area (29), forward the Objective Focal Lens Area (29).

The total coverage Diffusion Element (4) design type in combination with either a normal or small Opaque Light Masking Edge (7) opening can cause the Illumination Zone (10) to sometimes include a Diffused Illumination Interior (15D) free of visible Chromatic Aberration Particle (14D) with Diffusion Element (4) positioned either, within the Gate Area (21), within the Objective Focal Lens Area (29), or forward the Objective Focal Lens Area (29).

The total coverage Diffusion Element (4) design type in combination with either a normal or small Opaque Light Masking Edge (7) opening can cause the Illumination Zone (10) to sometimes include a low light intensity Binary Illumination Zone Edge (12B) finishing the Fade Out Border (17) free of a visible Chromatic Aberration Border (14) when Diffusion Element (4) is positioned within the Gate Area (21).

The total coverage Diffusion Element (4) design type in combination with either a normal or small Opaque Light Masking Edge (7) opening can cause an Illumination Zone (10) to sometimes include the Illumination Interior (15) having visible Chromatic Aberration Particle (14D) when Diffusion Element (4) is positioned within the Gate Area (21).

Combinations for a Peripheral Diffusion Element Design Type

Regardless of an optical light masking projector configuration including with or without a Condensing Lens (5), and depending on an Objective Focal Lens Sub-Assembly (30) focus, in combination with a peripheral Diffusion Element (4) design type inclusive of possible variation such as graduation or pattern(s), with the peripheral Diffusion Element (4) design type as a constituent part of a non-specific component form of any composition fabrication or modification method positioned within or forward the Gate Area (21) including outside of an optical light masking projector assembly, the Illumination Zone (10) includes at least one visual result when in combination with either a normal or small Opaque Light Masking Edge (7) opening.

The peripheral Diffusion Element (4) design type in combination with a normal Opaque Light Masking Edge (7) opening can cause the Illumination Zone (10) to sometimes include the Fade Out Border (17) free of a visible Chromatic Aberration Border (14) finishing with a low light intensity novel Diffused Illumination Zone Edge (12D) with Diffusion Element (4) positioned either, within the Gate Area (21), within the Objective Focal Lens Area (29), or forward the Objective Focal Lens Area (29).

The peripheral Diffusion Element (4) design type in combination with a normal Opaque Light Masking Edge (7) opening can cause the Illumination Zone (10) to sometimes include a low light intensity Binary Illumination Zone Edge (12B) finishing the Fade Out Border (17) free of a visible Chromatic Aberration Border (14) with Diffusion Element (4) positioned either, within the Gate Area (21), or forward the Objective Focal Lens Area (29).

The peripheral Diffusion Element (4) design type in combination with a small Opaque Light Masking Edge (7) opening can cause the Illumination Zone (10) to sometimes include the Fade Out Border (17) free of a visible Chromatic Aberration Border (14) finishing with the low light intensity Binary Illumination Zone Edge (12B) with Diffusion Element (4) positioned either, within or forward the Gate Area (21), or forward the Objective Focal Lens Area (29) including outside of an optical light masking projector assembly.

The peripheral Diffusion Element (4) design type in combination with a small Opaque Light Masking Edge (7) opening can cause the Illumination Zone (10) to sometimes include the Fade Out Border (17) free of a visible Chromatic Aberration Border (14) finishing with the Diffused Illumination Zone Edge (12D) with Diffusion Element (4) positioned either, within the Objective Focal Lens Area (29), or forward the Objective Focal Lens Area (29).

The peripheral Diffusion Element (4) design type in combination with either a normal or small Opaque Light Masking Edge (7) opening can cause a Diffused Illumination Interior (15D) in the center area of the Illumination Zone (10) free of Visible Chromatic Aberration Particle (14D) with Diffusion Element (4) positioned either, within the Gate Area (21), within the Objective Focal Lens Area (29), or forward the Objective Focal Lens Area (29).

Combinations for a Center Diffusion Element Design Type

Regardless of an optical light masking projector configuration with or without a Condensing Lens (5), and depending on an Objective Focal Lens Sub-Assembly (30) focus, in combination with a center Diffusion Element (4) design type inclusive of possible variation such as graduation or pattern(s), with the center Diffusion Element (4) design type as a constituent part of a non-specific component form of any composition fabrication or modification method positioned within or forward the Gate Area (21) including outside of an optical light masking projector assembly, the Illumination Zone (10) includes at least one visual result when in combination with either a normal or small Opaque Light Masking Edge (7) opening.

The center Diffusion Element (4) design type in combination with a small Opaque Light Masking Edge (7) opening can cause the Illumination Zone (10) to sometimes include the Fade Out Border (17) free of a visible Chromatic Aberration Border (14) finishing with a low light intensity novel Diffused Illumination Zone Edge (12D) with Diffusion Element (4) positioned either, within the Gate Area (21), within the Objective Focal Lens Area (29), or forward the Objective Focal Lens Area (29).

The center Diffusion Element (4) design type in combination with a small Opaque Light Masking Edge (7) opening can cause the Illumination Zone (10) to sometimes include a Diffused Illumination Interior (15D) free of visible Chromatic Aberration Particle (14D) with Diffusion Element (4) positioned either, within the Gate Area (21), within the Objective Focal Lens Area (29), or forward the Objective Focal Lens Area (29).

The center Diffusion Element (4) design type in combination with a small Opaque Light Masking Edge (7) opening can cause the Illumination Zone (10) to sometimes include the Fade Out Border (17) free of a visible Chromatic Aberration Border (14) finishing with a low light intensity Binary Illumination Zone Edge (12B) when Diffusion Element (4) is positioned within or forward the Gate Area (21) including outside of an optical light masking projector assembly.

The center Diffusion Element (4) design type in combination with a normal Opaque Light Masking Edge (7) opening can cause the Illumination Zone (10) to sometimes include the Fade Out Border (17) free of a visible Chromatic Aberration Border (14) finishing with a low light intensity Diffused Illumination Zone Edge (12D) with Diffusion Element (4) positioned either, within the Gate Area (21), within the Objective Focal Lens Area (29), or forward the Objective Focal Lens Area (29).

The center Diffusion Element (4) design type in combination with a small Opaque Light Masking Edge (7) opening can cause the Illumination Zone (10) to sometimes include an Illumination Interior (15) having visible Chromatic Aberration Particle (14D) with Diffusion Element (4) positioned either, within the Gate Area (21), within the Objective Focal Lens Area (29), or forward the Objective Focal Lens Area (29).

### CONCLUSION

Following is the conclusion for placement of a non-specific Diffusion Element (4) of any design type inclusive of possible variation such as graduation or pattern(s), with the non-specific Diffusion Element (4) being a constituent part of a non-specific component form of any composition fabrication or modification method in any position within or forward the Gate Area (21) including outside of an optical light masking projector assembly, capable of causing at least one novel visual result from an optical light masking projector assembly of any configuration.

An embodiment includes a method that eliminates a visible Chromatic Aberration Border (14) regardless of an optical light masking projector configuration, including with or without a Condensing Lens (5), and when in combination with only one and either, a total coverage Diffusion Element (4) design type, a peripheral Diffusion Element (4) design type, or a center Diffusion Element (4) design type, with the Diffusion Element (4) being non-specific and a constituent part of a non-specific component form of any composition fabrication or modification method in any position within or forward the Gate Area (21), and with Objective Focal Lens Sub-Assembly (30), sometimes in-focus, sometimes slightly out-of-focus, while other times having to be completely out-of focus, capable of causing the Illumination Zone (10) to include the Fade Out Border (17) free of a visible Chromatic Aberration Border (14).

Regardless of an optical light masking projector configuration including with or without a Condensing Lens (5), and when in combination with only one and either, a total coverage Diffusion Element (4) design type, a peripheral Diffusion Element (4) design type, or a center Diffusion Element (4) design type, with the Diffusion Element (4) being non-specific and a constituent part of a non-specific component form of any composition fabrication or modification method in any position within or forward the Gate Area (21) including outside of an optical light masking projector assembly, and with Objective Focal Lens Sub-Assembly (30) sometimes in-focus, sometimes slightly out-of-focus while other times having to be completely out-of focus; capable of causing the Illumination Zone (10) to sometimes include either a non-Diffused Illumination Interior (15) or a Diffused Illumination Interior (15D) with the Diffused Illumination Interior (15D) sometimes eliminating visible Chromatic Aberration Particle (14D); capable of causing the Illumination Zone (10) to include the Fade Out Border (17) free of a visible Chromatic Aberration Border (14) finishing with a surrounding low light intensity Binary Illumination Zone Edge (12B); capable of causing the Illumination Zone (10) to include the Fade Out Border (17) free of a visible Chromatic Aberration Border (14) finishing with a surrounding low light intensity novel Diffused Illumination Zone Edge (12D) providing a visual result that also decreases the difficulty of fashioning a visually correct Opaque Light Masking Edge (7).

The various embodiments described above are provided by way of illustration only and should not be construed to limit the claimed invention. Those skilled in the art will readily recognize various modifications and changes that may be made to the claimed invention without following the example embodiments and applications illustrated and described herein, and without departing from the true spirit and scope of the claimed invention, which is set forth in the following claims. In that regard, various features from certain of the disclosed embodiments can be incorporated into other of the disclosed embodiments to provide desired structure.

What is claimed is:

1. A light projector system, comprising:
a light projector device including a light source for producing a light beam, a light mask, an objective focal lens disposed within the path of the light beam, and a gate area; and
a diffusion element disposed within the gate area along the path of the light beam of the projector device.

2. The system of claim 1, wherein the diffusion element is integrated with a lens to form a diffusion lens.

3. The system of claim 1, wherein the light projector device includes a reflector.

4. The system of claim 3, wherein the diffusion element is integrated with the reflector.

5. The system of claim 1, wherein the light projector device includes a condensing lens.

6. The system of claim 5, wherein the diffusion element is integrated with the condensing lens.

7. The system of claim 1, wherein the light projector device includes a prism disposed in the path of the light beam.

8. The system of claim 7, wherein the diffusion element is integrated with the prism.

9. A light projector system, comprising:
a light projector device including a light source for producing a light beam, a light mask having an opaque light masking edge, an objective focal lens disposed within the path of the light beam, and a gate area; and
a diffusion element integrated with the light mask and disposed within the gate area along the path of the light beam of the projector device.

10. The system of claim 9, wherein the diffusion element integrated with the light mask forms at least a portion of a translucent light mask plate.

11. The system of claim 10, wherein the translucent light mask plate includes a light blocking material.

12. The system of claim 9, wherein the diffusion element integrated with the light mask forms at least a portion of a translucent light mask shutter.

13. The system of claim 12, wherein the translucent light mask shutter includes a light blocking material.

14. The system of claim 9, wherein the diffusion element integrated with the light mask forms at least a portion of a photosensitized translucent light mask plate.

15. The system of claim 14, wherein the photosensitized translucent light mask plate includes a photosensitized layer element and a light blocking material element.

16. A light projector system, comprising:
a light projector device including a light source for producing a light beam, a light mask, an objective focal lens disposed within the path of the light beam, and a gate area; and
a diffusion element disposed forward of the gate area along the path of the light beam.

17. The system of claim 16, wherein the diffusion element is integrated with a lens to form a diffusion lens.

18. The system of claim 16, further comprising a reflector disposed within the path of the light beam.

19. The system of claim 18, wherein the diffusion element is integrated with the reflector.

20. The system of claim 16, wherein the diffusion element is integrated with the objective focal lens.

21. The system of claim 16, further comprising a prism disposed within the path of the light beam.

22. The system of claim 21, wherein the prism is integrated with an objective focal lens.

23. The system of claim 22, wherein the diffusion element is integrated with the prism having an integral objective focal lens.

24. The system of claim 16, further comprising a corrective lens disposed within the path of the light beam.

25. The system of claim 24, wherein the diffusion element is integrated with the corrective lens.

26. A method for creating a light projector system, the method comprising:
providing a light source for producing a light beam;
providing a light projector device including a light mask positioned in a gate area of the light projector device, and an objective focal lens positioned forward of the gate area, wherein the light mask and objective focal lens are disposed within the path of the light beam; and
positioning a diffusion element within the gate area of the light projector device and along the path of the light beam produced by the light source.

27. The method of claim 26, wherein the diffusion element eliminates visible chromatic aberration from an illumination zone produced by the light projector system.

28. The method of claim 26, wherein the light source is a part of a rear sub-assembly and the diffusion element is a part of a front sub-assembly.

29. The method of claim 28, further comprising attaching the front sub-assembly to the rear sub-assembly to create the light projector system.

30. The method of claim 28, further comprising securing the rear sub-assembly adjacent to the front sub-assembly.

31. The method of claim 26, wherein the diffusion element is integrated with a lens to form a diffusion lens.

32. The method of claim 26, wherein the light source is housed within the light projector device.

33. A method for creating a light projector system, the method comprising:
providing a light source for producing a light beam;
providing a light projector device including a light mask positioned in a gate area of the light projector device, and an objective focal lens positioned forward of the gate area; and
positioning a diffusion element forward of a gate area of the light projector device and along the path of the light beam produced by the light source.

34. The method of claim 33, wherein the diffusion element eliminates visible chromatic aberration from an illumination zone produced by the light projector system.

35. The method of claim 33, wherein the light source is a part of a rear sub-assembly and the diffusion element is a part of a front sub-assembly.

36. The method of claim 35, further comprising attaching the front sub-assembly to the rear sub-assembly to create the light projector system.

37. The method of claim 35, further comprising securing the rear sub-assembly adjacent to the front sub-assembly.

38. The method of claim 33, wherein the diffusion element is integrated with a lens to form a diffusion lens.

39. The method of claim 33, wherein the light source is housed within the light projector device.
